(19) United States
(12) Patent Application Publication
(10) Pub. No.: US 2008/0192544 A1
(43) Pub. Date: Aug. 14, 2008

(54) Error correction coding techniques for non-volatile memory

(76) Inventors: Amit Berman, Nahariya (IL); Avi Lavan, Yokneam-Elit (IL)

Correspondence Address: EMPK & Shiloh, LLP, 116 JOHN ST,, SUITE 1201, NEW YORK, NY, 10038, US

(21) Appl. No.: 12/068,787

(22) Filed: Feb. 12, 2008

Related U.S. Application Data
(60) Provisional application No. 60/900,985, filed on Feb. 13, 2007.

(51) Int. Cl. G11C 16/04; G11C 16/06

(52) U.S. Cl. 365/185.09; 365/185.18

(57) ABSTRACT

During programming of memory cells, calculating sigma bits for cells programmed at each program level based on attributes of the cells, such an index representing a cell's bit location in the memory array. For example, summing the indexes with an increasing weight factor, such as factor-of-2. During read, new sigma bits are calculated and compared with the stored sigma bits. A difference between the new sigma bits and the stored sigma bits may define a unique combination of indexes, enabling searching for, finding and correcting the read errors. The sigma bits may be used to correctly identify which cells were programmed at which program level, despite threshold voltage drift and/or overlap. Programming may be performed with advertent overlapping distributions, and the bits can be sorted out.

### CROSS-REFERENCE(S) TO RELATED APPLICATION(S)

This application claims the benefit of U.S. Provisional Patent Application No. 60/900,985 filed Feb. 13, 2007 which is hereby incorporated by reference in it's entirety.

### TECHNICAL FIELD

The disclosure relates to techniques for operating semiconductor devices and, more particularly, to operating non-volatile memory (NVM), such as floating gate (FG) devices or charge-trapping devices such as silicon oxide nitride oxide semiconductor (SONOS), tantalum nitride oxide semiconductor (TANOS) and nitride read only memory (NROM), or other microelectronic cells or structures.

### BACKGROUND

The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals. One type of transistor is known as the field effect transistor (FET).

The terminals of a field effect transistor (FET) are commonly named source (S), gate (G) and drain (D). In the FET a small amount of voltage is applied to the gate (G) in order to control current flowing between the source (S) and the drain (D). In FETs the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate (or a p-well in the substrate), and two spaced-apart n-type diffusion areas—one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric under the gate is also commonly referred to as “gate oxide” or “gate dielectric”.) Electrical connections (not shown) may be made to the source, the drain, and the gate. The substrate may be grounded, or it may be biased at a desired voltage, depending on applications.

Generally, when there is no voltage on the gate, there is no electrical conduction (connection) between the source and the drain. As voltage (of the correct polarity) is applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

The FET 100 is exemplary of a MOSFET (metal oxide semiconductor FET) transistor. With the specified “n” and “p” types shown above, an “n-channel MOSFET” can be formed. With opposite polarities (swapping “p” for “n” in the diffusions, and “n” for “p” in the substrate or well), a p-channel FET can be formed. In CMOS (complementary metal oxide semiconductor), both n-channel and p-channel MOS transistors may be used, and are often paired with one another.

An integrated circuit (IC) device may comprise many millions of FETs on a single semiconductor “chip” (or “die”), measuring only a few centimeters on each side. Several IC chips may be formed simultaneously, on a single “wafer”, using conventional semiconductor fabrication processes including deposition, doping, photolithography, and etching. After all the chips are formed, they can be singulated from the wafer.

The Floating Gate Transistor

A floating gate transistor is generally a transistor structure, broadly based on the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor; the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges from the floating gate, are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “1”.) That represents the programming “half” of how a floating gate memory cell operates. The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Normally, the floating gate non-volatile memory (NVM) cell has only a single “charge-storing area”—namely, the conductive floating gate (FG) structure, and can therefore only store a single bit of information (binary “1” or binary “0”). More recently, using a technology referred to as “multi-level cell” (MLC), two or more bits can be stored in and read from the floating gate cell.

The NROM Memory Cell

Another type of memory cell, called a “nitride, read only memory” (NROM) cell, has a charge-storage structure which is different from that of the floating gate memory cell and which permits charges to be stored (or trapped) in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around, as in the example of the conductive floating gate of the floating gate memory cell. A first bit of binary information (binary “1” or binary “0”) can be stored in a first portion (such as the left-hand side) of the charge-trapping medium, and a second bit of binary information (binary “1” or binary “0”) can be stored in a second portion (such as the right-hand side) of the charge-trapping medium. An alternative viewpoint is that different charge concentrations can be considered for each bit of storage. Using MLC technology, at least two bits can be stored in and read from each of the two portions (charge storage areas) of the charge-trapping medium (for a total of 4 bits), similarly 3 bits or more than 4 bits may be identified.

FIG. 3 illustrates a basic NROM memory cell, which may be viewed as an FET with an “ONO” structure inserted between the gate and the substrate. (One might say that the ONO structure is “substituted” for the gate oxide of the FET.)

The ONO structure is a stack (or “sandwich”) of bottom (lower) oxide 322, a charge-trapping material such as nitride 324, and a top (upper) oxide 326. The ONO structure may have an overall thickness of approximately 10-25 nm, such as 18 nm, as follows:
the bottom oxide layer 322 may be from 3 to 6 nm, for example 4 nm thick;
the middle nitride layer 324 may be from 3 to 8 nm, for example 4 nm thick; and
the top oxide layer 326 may be from 5 to 15 nm, for example 10 nm thick.

The NROM memory cell has two spaced apart diffusions 314 and 316 (which can function as source and drain, as discussed hereinbelow), and a channel region 320 defined in the substrate 312 between the two diffusion regions 314 and 316, and a gate 328 disposed above the ONO stack 321.

In FIG. 3, the diffusions are labeled “N+”. This means that they are regions in the substrate that have been doped with an electron donor material, such as phosphorous or arsenic. These diffusions are typically created in a larger region which is a p-type cell well (CW) doped with boron (or indium or both). This is the normal “polarity” for an NVM cell employing electron injection (but which may also employ hole injection, such as for erase). With opposite polarity (boron or indium implants in an n-type cell well), the primary injection mechanism would be for holes, which is generally accepted to be not as effective as electron injection. One skilled in the art will recognize that the concepts disclosed herein can be applied to opposite polarity devices.

The charge-trapping material 324 is non-conductive, and therefore, although electrical charges can be stored in the charge-trapping material, they are not free to move around; they will generally stay where they are stored. Nitride is a suitable charge-trapping material.

Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of storing at least two bits of data—at least one bit(s) in a first storage area of the nitride layer 324 represented by the dashed circle 323, and at least one bit(s) in a second storage area of the nitride layer 324 represented by the dashed circle 321. Thus, the NROM memory cell can be considered to comprise two “half cells”, each half cell capable of storing at least one bit(s). It should be understood that a half cell is not a physically separate structure from another half cell in the same memory cell. The term “half cell”, as it may be used herein, is used herein only to refer to the “left” or “right” bit storage area of the ONO stack (nitride layer). The storage areas 321, 323 may variously be referred to as “charge storage areas”, “charge trapping areas”, and the like, throughout this document. (The two charge storage areas may also be referred to as the right and left “bits”.)

Each of the storage areas 321, 323 in the charge-trapping material 324 can exert a field effect on the channel region 320 between the source and the drain, in a manner similar to how a normal FET works, as described hereinabove (FIG. 2).

Generally, if a charge is stored in a given storage area of the charge-trapping material, this represents a binary “1”, and if no charge is stored in a given storage area of the charge-trapping material, this represents a binary “0”. (Again, these designations are arbitrary, and can be reversed so that the charged state represents binary “0” and the discharged state represents binary “1”.) That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is.

Modes of Operation

Generally, the modes of operation for any NVM memory cell (either floating gate, SONOS, TANOS, NROM or other) include “program”, “erase” and “read”. Modes of operation for NROM are now discussed.

Program generally involves injecting electrons into the charge storage areas of the NROM cell, typically by a process known as channel hot electron (CHE) injection. Exemplary voltages to program (by CHE injection of electrons) the right bit (right bit storage area) of an NROM cell,
the left BL (acting as source, Vs) is set to 0 volts
the right BL (acting as drain, Vd) is set to +5 volts
the gate (Vg) is set to +8-10 volts
the substrate (Vb) is set to 0 volts

and the bit storage area above the drain (right BL) becomes programmed. To program the left bit storage area, source and drain are reversed—the left bitline serves as the drain, and the right bitline serves as the source.

Erase may involve injecting holes into the charge storage areas of the NROM cell, typically by a process known as hot hole injection (HHI). Generally, holes cancel out electrons (they are electrically opposite), on a one-to-one basis. Exemplary voltages to erase (by HHI injection of holes) the right bit of the NROM cell,
the left BL (acting as source, Vs) is set to float
the right BL (acting as drain, Vd) is set to +5 volts
the gate (Vg) is set to −7 volts
the substrate (Vb) is set to 0 volts

and the bit storage area above the drain (right BL) becomes erased. To erase the left bit storage area, source and drain are reversed—the left bitline serves as the drain and the right bitline serves as the source.

Read may involve applying voltages to the terminals of the memory cell and, based on subsequent current flow, ascertaining the threshold voltage of the charge storage area within the cell. Generally, to read the right bit of the NROM cell, using “reverse read”,
the right BL (acting as source, Vs) is set to 0 volts
the left BL (acting as drain, Vd) is set to +2 volts
the gate (Vg) is set to +5 volts
the substrate (Vb) is set to 0 volts

and the bit storage area above the source (right BL) can be read. To read the left bit storage area, source and drain are reversed—the left bitline serves as the source, and the right bitline serves as the drain.

“Reading” an NROM Cell, generally

Reading an NROM memory cell may involve applying voltages to the terminals of the memory cell comparable to those used to read a floating gate memory cell, but reading may be performed in a direction opposite to that of programming. Generally, rather than performing “symmetrical” programming and reading (as is the case with the floating gate memory cell, described hereinabove), the NROM memory cell is usually programmed and read “asymmetrically”, meaning that programming and reading occur in opposite directions. This is illustrated by the arrows in FIG. 3. Programming is performed in what is termed the forward direction, and reading is performed in what is termed the opposite or reverse direction. For example, generally, to program the right storage area 323 (in other words, to program the right “bit”), electrons flow from left (source) to right (drain). To read the right storage area 323 (in other words, to read the right “bit”), voltages are applied to cause electrons to flow from right to left, in the opposite or reverse direction. For example, generally, to program the left storage area 321 (in other words, to program the left “bit”), electrons flow from right (source) to left (drain). To read the left storage area 321 (in other words, to read the left “bit”), voltages are applied to cause electrons to flow from left to right, in the opposite or reverse direction. See, for example, U.S. Pat. No. 6,768,165.

Memory Array Architecture, Generally

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

As discussed hereinabove, each memory cell comprises a first diffusion (functioning as source or drain), a second diffusion (functioning as drain or source) and a gate, each of which has to receive voltage in order for the cell to be operated, as discussed hereinabove. Generally, the first diffusions (usually designated “source”) of a plurality of memory cells are connected to a first bit line which may be designated “BL(n)”, and second diffusions (usually designated “drain”) of the plurality of memory cells are connected to a second bit line which may be designated “BL(n+1)”. Typically, the gates of a plurality of memory cells are connected to common word lines (WL).

The bitlines may be “buried bitline” diffusions in the substrate, and may serve as the source/drain diffusions for the memory cells. The wordlines may be polysilicon structures and may serve as the gate elements for the memory cells.

FIG. 4A illustrates an array of NROM memory cells (labeled “a” through “i”) connected to a number of word lines (WL) and bit lines (BL). For example, the memory cell “e” has its gate connected to WL(n), its source (left hand diffusion) is connected to BL(n), and its drain (right hand diffusion) is connected to BL(n+1). The nine memory cells illustrated in FIG. 4 are exemplary of many millions of memory cells that may be resident on a single chip.

Notice, for example, that the gates of the memory cells “e” and “f” (to the right of “e”) are both connected to the same word line WL(n). (The gate of the memory cell “d” to the left of “e” is also connected to the same word line WL(n).) Notice also that the right hand terminal (diffusion) of memory cell “e” is connected to the same bit line BL(n+1) as the left-hand terminal (diffusion) of the neighboring memory cell “f”. In this example, the memory cells “e” and “f” have two of their three terminals connected together.

The situation of neighboring memory cells sharing the same connection—the gates of neighboring memory cells being connected to the same word line, the source (for example, right hand diffusion) of one cell being connected to the drain (for example left hand diffusion) of the neighboring cell—is even more dramatically evident in what is called “virtual ground architecture” wherein two neighboring cells actually share the same diffusion. In virtual ground array architectures, the drain of one memory cell may actually be the same diffusion which is acting as the source for its neighboring cell. Examples of virtual ground array architecture may be found in U.S. Pat. Nos. 5,650,959; 6,130,452; and 6,175,519, incorporated in their entirety by reference herein.

Operating Flash Memory

Flash is a non-volatile memory that can retain the data stored therein even after power is removed. NAND Flash, which is one type of Flash, is high-density design and has certain advantages over other types of memory, including a large storage capacity (such as one giga-bits or more), good speed for continued access, and low cost. However, NAND Flash also has several inherent drawbacks, including poor performance for random access and increased susceptibility to bit errors over the NAND Flash's operating lifetime. In particular, NAND Flash is typically accessed in units of pages, one page at a time, with each page being of a particular size (for example, 512 bytes).

Because the structure of NAND Flash is not suitable for random access, program codes cannot be executed directly from the NAND Flash. Instead, Static Random Access Memory (SRAM) or NOR Flash may be used as an intermediate storage for data and program codes that need to be accessed in a random manner by the processor. A memory architecture that incorporates both SRAM and NAND Flash or NOR and NAND Flash (with our without SRAM) may thus provide large storage capacity, reduced cost, and random access.

Conventionally, reading data from or writing data into NAND Flash requires excessive involvement and control by the processor. This can tie up the processor and prevent it from performing other functions, which can then result in overall performance degradation for the communication device. Moreover, since NAND Flash is more prone to bit errors, a mechanism is needed to ensure data integrity when loading data from or into the NAND Flash.

As described in U.S. Pat. No. 6,967,896, a user wishing to write data to an NVM array may typically write the data to a cache memory, such as but not limited to, a static random access memory (SRAM). The cache memory routes or “addresses” the data to the appropriate bits in the NVM array. The data may be written to the SRAM in a byte granularity.

In a manner similar to NVM, SRAM may also be arranged in an array—for example, an N×n array of 1-bit cells, where:
n=byte width (such as 8, 16, 32 . . . )
N=number of bytes

Generally, m address bits may be divided into x row bits and y column bits (x+y=m). Address bits may be encoded such that 2^{m}=N, and the array may be organized with both vertical and horizontal stacks of bytes.

An example of a typical SRAM addressing scheme is shown in the following table.

| | Columns | | | |
|---|---|---|---|---|
| Rows | C0 | C1 | C2 | C3 |
| R0 | Address = 0 | Address = 1 | Address = 2 | Address = 3 |
| | Data = x0 | Data = x1 | Data = x2 | Data = x3 |
| R1 | Address = 4 | Address = 5 | Address = 6 | Address = 7 |
| | Data = x4 | Data = x5 | Data = x6 | Data = x7 |
| R2 | Address = 8 | Address = 9 | Address = 10 | Address = 11 |
| | Data = x8 | Data = x9 | Data = x10 | Data = x11 |
| R3 | Address = 12 | Address = 13 | Address = 14 | Address = 15 |
| | Data = x12 | Data = x13 | Data = x14 | Data = x15 |

FIG. 4B illustrates, in a general manner, the concept that data is “buffered” in cache memory (such as SRAM) prior to being written to an NVM array (such as the NROM array shown in FIG. 4A) and when being read from the NVM array. The data may be in the form of a data stream which is accumulated by the SRAM into blocks, prior to writing to the NVM array. The SRAM may also serialize chunks of data which are read from the NVM array. The cache memory may be on the same chip as the NVM array.

More on Reading The State Of The Memory Cells

A memory cell may be programmed to different states, or program levels, determined by the threshold voltage (Vt) of the cell. For a single level cell (SLC), there are two program levels, generally “erase” and “program”. For a multi-level cell (MLC) there are more than two program levels. An NVM cell's state may be defined and determined by its threshold voltage (Vt), the voltage at which the cell begins to conduct current. An NVM cell's threshold voltage level is usually correlated to the amount of charge stored in a charge storage region of the cell. Different threshold voltage ranges are associated with different states or program levels of an NVM cell.

Generally, in order to determine the state (program level) of an NVM cell, the cell's threshold level may be compared to that of a reference structure or cell whose threshold level is set, or otherwise known to be, at a voltage level associated with the specific state being tested for. Comparing the threshold voltage of an NVM cell to that of a reference cell is often accomplished using a sense amplifier or similar circuit. Various techniques for comparing an NVM cell's threshold voltage against those of one or more reference cells or structures, in order to determine the NVM cell's state, are well known.

When reading a NVM cell, to determine whether it is at a particular state, the cell's threshold voltage may be compared against that of a reference cell having a reference threshold voltage defined as a “read” level for the specific state. A “read” level is usually set lower than a program verify (PV) level and higher than the erase verify (EV) level in order to compensate for voltage drifts which may occur during operation.

In a “binary” or single level cell (SLC) capable of storing only one bit of information (a logic 1 or a logic 0), only a single read verify (RV) voltage is required, and it may be between the erase verify (EV) and program verify (PV) voltages for the cell.

“Read” is generally done by measuring the Vt of a cell (or half-cell), and associating the measured Vt with a program level (such as “0” or “1”). Although the Vt's of the cells are measured on an individual basis, it is generally necessary to determine a distribution of Vt's for many cells in order to associate the measured Vt of a given cell with a program level, with confidence. For example—if only one cell were to be read, and its threshold voltage were to be found to be at or very near the Read Verify (RV) voltage between two program levels, it may be difficult to say, with certainty, at which of two program levels the single cell was programmed, since its threshold voltage may have moved slightly upward or slightly downward since it was programmed. This is a benefit of reading bits one block at a time—to obtain a statistically meaningful sample of Vt's across a number of cells.

FIG. 5A is a graph illustrating two states of a “binary” or single level cell (SLC) capable of storing one bit of information per cell (or per charge trapping area with an NROM cell), and utilizes only one read verify threshold (RV). Generally, the two states are erased (represented by “1”) and programmed (represented by “0”). The horizontal axis is threshold voltage (Vt), increasing from left to right.

Three voltage levels are illustrated in FIG. 5A, these are EV (erase verify), RV (read verify) and PV (program verify). As illustrated, EV is less than RV, which is less than PV. A high VT may represent a program state of binary “0”, and a low Vt may represent an erase state of binary “1”. The binary designations are arbitrary, and may be reversed (high Vt=“1”, low Vt=“0”).

FIG. 5A is generalized, and is applicable to a typical floating gate NVM memory cell or a given charge storage area of an NROM cell. The curves represent the threshold voltages (Vts) for a number of cells at the given program level. Typically, there is a distribution, or spread, about a nominal (or average, or center) value. For example,
the center value for “1” equals approximately 3.5 volts
the center value for “0” equals approximately 6.0 volts
EV equals approximately 4.0 volts
RV equals approximately 4.5 volts
PV equals approximately 5.5 volts

FIG. 5B illustrates a situation wherein there are four possible MLC program levels (or states) 11, 01, 00, 10 for each memory cell (or, in the case of NROM, for each storage area of the memory cell). As illustrated, the program level 11 has the lowest Vt, the program level 01 has a higher Vt, the program level 00 has a yet higher Vt, and the program level 10 has a yet higher Vt. The program level 11 may be erase (ERS), which for purposes of this discusson is considered to be a program level, although it is not generally regarded as such.

There are a number of memory cells (or storage area NROM cells) being programmed, erased and read. In a given array, or on a given memory chip, there may be many millions of memory cells. Programming may typically be performed in blocks of thousands of memory cells. The different blocks of memory cells are typically located at different logical positions within the array, and at different physical positions on the chip. During (or before) programming, a check sum indicative of the number of cells programmed to each level may be stored in the block, in the array, on the chip, or external to the chip.

At each program level (and this is also true for the SLC cell of FIG. 5A), there is typically a distribution of threshold voltages within a range (a statistical spread). In other words, for a given program level, the threshold voltage is not likely to be exactly a unique, precise voltage for all of the memory cells being programmed to that level. Initially, in the act of programming the cell, the voltage may be off a bit, for example, as a result of the state of neighboring cells (or the other charge storage area in the same NROM cell), or, as a result of previous program or erase operations on the same cell, or neighboring cells, or, as a result of a variety of other factors. After programming, the threshold voltage of a cell may change, as a result of programming neighboring cells (or the other charge storage area in the same NROM cell), or a variety of other factors.

Therefore, the threshold voltage (Vt) for a given program level may be more than average in some cells, in others it may be less than average. Nevertheless, in a properly functioning group of cells (such as a block, or an array), there should be a clear distribution of four distinct program levels, such as illustrated. The distributions of Vt for each of the program levels should be separated enough from one another so that read positions (RV voltage levels) can be established between adjacent distributions of threshold voltages, such as the following:

RV01 is between EV and PV01, or higher than the highest expected Vt for a cell at state “11” and lower than the lowest expected Vt for a cell at state “01”;

RV00 is between PV01 and PV00, or higher than the highest expected Vt for a cell at state “01” and lower than the lowest expected Vt for a cell at state “00”; and

RV 10 is between PV00 and PV10, or higher than the highest expected Vt for a cell at state “00” and lower than the lowest expected Vt for a cell at state “10”.

For example,
the center value for “11” equals approximately 4.0 volts
the center value for “01” equals approximately 4.4 volts
the center value for “00” equals approximately 4.8 volts
the center value for “10” equals approximately 5.4 volts
EV equals approximately 4.0 volts
RV01 equals approximately 4.4 volts
PV01 equals approximately 4.8 volts
RV00 equals approximately 5.4 volts
PV00 equals approximately 5.6 volts
RV10 equals approximately 6.0 volts
PV10 equals approximately 6.3 volts

An Aside About Binary Notation and the Labeling of Program Levels “Binary” generally means “two”. In binary notation, there are only two possible digits, usually referred to as “1” and “0”. Many 1s and 0s can be strung together to represent larger numbers, for example:
0000 is zero
0001 is one
0010 is two
0011 is three
0100 is four
1000 is eight
1010 is ten

In the examples above, the binary numbers have four digits each—four “places”. For purposes of this disclosure, only two digits will be used. Two digits can represent four numbers. Counting (in binary) typically starts with zero, and counting from zero to three proceeds like this: 00 (zero), 01 (one), 10 (two), 11 (three). Notice, in the transition from 01 (one) to 10 (two), both bits change.

Since it is arbitrary which program levels represent which digits, notice in FIG. 5B that the program levels appear to be out of sequence, starting with 11 (three), then 01 (one), then 00 (zero), then 10 (two). This sequence is common, so that when moving from one program level to the next higher level, both bits do not change—as is the case with the transition from 01 (one) to 10 (two). In FIG. 5B it can be seen that when moving from one program level to another, only one of the bits changes.

Threshold Voltage Drift

The threshold voltage of an NVM cell seldom stays fixed (after it is programmed, or erased). Threshold voltage drift is a phenomenon which may result in large variations of the threshold voltage of a memory cell. These variations may occur due to charge leakage from the cell's charge storage region, temperature changes, and interference from the operation of neighboring NVM cells.

The drift in threshold voltage of a memory cell is well known, and is discussed, for example, in U.S. Pat. Nos. 6,992,932 and 6,963,505 which discloses read error detection in an NVM array, and may hereinafter be referred to as the “moving reference patent(s)”. These deviations in a cell's thresthold voltage (Vt) may be either in the upward or downward direction, and may vary from cell to cell.

Variation of the threshold voltage of memory cells may lead to false reads of the cell's state and may further result in the corruption of the data in the memory array. Voltage drift is especially problematic in MLC cells (see FIG. 5A) where the Vt regions or sub-ranges associated with each programmed state are relatively smaller than those for a typical binary or SLC cell (see FIG. 5B).

It is known that, in order to reduce data loss and data corruption due to drift in the threshold voltages of the cells of an NVM array, threshold voltage drift of cells in the NVM array should be compensated for.

The moving reference patents disclose that, for a given NVM array, it is known to provide one or a set of reference cells whose references' threshold voltages are offset from defined verify threshold levels by some value related to the actual voltage drift experienced by the NVM cells to be read. There is a well understood need for an efficient and reliable method of determining a set of reference voltage levels which may accommodate variations in the threshold voltages of cells of an NVM array, and of established reference cells with the determined reference voltages.

Generally, at least a subset of cells of an NVM block (or array) may be read, and the number of cells found at a given state (such as logic “0”, or “00”) associated with the block may be compared to one or more check sum values obtained during programming of the at least a subset of cells. A Read Verify threshold reference voltage associated with the given program state or associated with an adjacent state may be adjusted based on the result of the comparison.

Generally, the idea presented in the aforementioned moving reference patents is to select (establish) a set of reference cells (from N sets) to be used in operating an NVM block or array. For example, each set of test reference cells may have reference voltages at least slightly offset from each other set of test reference cells. For example, each set of test reference cells may be incrementally offset, such that each set may be associated with a series of threshold voltages that are slightly higher than a corresponding series of threshold voltages associated with the previous set of test reference cells (excluding the first set). As a further example, if the first set of test reference cells includes cells having reference voltages: Cell 1=4.2V, Cell 2=5.2V, Cell3=6.2V, the second set may include cells having reference voltages offset, such that: Cell 1=4.3V, Cell 2=5.3V, Cell3=6.3V.

A set of reference voltages associated with the selected test set may be obtained by a controller. The set of reference voltages may be recorded, for example, in an error rate table. The controller may instruct an offset circuit to offset the threshold voltages of one or more of the reference cells in a set of global reference cells in accordance with the set of reference voltages. The controller may instruct the offset circuit to offset the reference voltages of one or more of the global reference cells in the set of global reference cells, such that the threshold voltages of the set of global reference cells may be substantially equal to the threshold voltages of the selected test set.

The offset circuit and the set of global reference cells may be substituted with a bank of reference cells (not shown). The bank of reference cells may include two or more reference cells, each reference cell in the bank being incrementally offset from the other reference cells in the bank. For example, each reference cell in the bank may have a threshold voltage that is slightly higher than the threshold voltage of the previous reference cell (excluding the first reference cell).

Once selected, the selected set of test reference cells may be used to determine which of the reference cells in the bank of reference cells is to be used for establishing an operating set of reference cells. The selected set of reference cells from the bank of reference cells may be selected such that the selected set from the bank may have reference voltages that are substantially equal to those of the selected test set. Thus, the selected set of reference cells from the bank may provide a set of operating reference cells having reference voltages substantially equal to those of the selected test set. The set of operating reference cells may be used to operate the NVM array.

Determining that Shifting RV is Necessary

Prior to or during the programming of a set of cells in an NVM array, the number of cells to be programmed to each of one or more logical or program states associated with the set of cells may be counted, and may be stored, for example, in a check sum table. The number of cells to be programmed to, up to and/or below each logical or program state may be counted and/or stored in a table which is either on the same array as the set of NVM cells or in memory on the same chip as the NVM array.

Upon the reading of the set of programmed cells, the number of cells found to be at a given logical or program state may be compared against either corresponding values stored during programming (such as the number of cells programmed to a given state) or against a value derived from the values stored during programming (such as the number of cells programmed at or above the given state, minus the number of cells programmed to or above an adjacent higher logical state).

If there is a discrepancy between the number of cells read at a given state and an expected number based on the values determined/counted/stored during programming, a Read Verify reference threshold value associated with the given program state may be adjusted upward or downward to compensate for the detected error. The read verify level of an adjacent logical state may also be moved upward or downward in order to compensate for detected read errors at a given state.

For example, if the number of cells found (read) in a given program state is below an expected value, either the Read Verify reference voltage associated with that given state may be reduced, or if there is found that the number of cells read above the given state exceeds an expected number, the Read Verify reference associated with a logical state higher and adjacent to the given state may be raised. Conversely, if the number of cells found. (for example, read) in a given program state is above expectations, either the Read Verify reference voltage associated with that given state may be increased, or if there is found that the number of cells read above the given state is below an expected number, the Read Verify reference associated with a logical state higher and adjacent to the given state may be lowered. Thus, Read Verify reference voltages for a set of cells may be selected such that the number of cells found/read in each of the states associated with the set may be substantially equal to the number either read from or derived from the values counted during programming of the set of cells, which values may have been stored in a check sum table.

The check sum table may reside on the same chip as the set of NVM cells, and a controller may be adapted to perform the above-mentioned error detection and Read Verify reference value adjustments. The check sum table may either be stored in the same NVM array as the set of NVM cells, or on some other memory cells residing on the same chip as the NVM array, for example, in a register or buffer used by the controller during programming and/or reading. Specialized error coding and detection circuits may be included with a controller on the same chip and the NVM array to be operated.

During the reading of the cells from the programmed set of cells, either the controller or some other error detection circuit may compare the number of cells counted in each program state during reading with the corresponding check sum values stored during or prior to programming. For example, if the number of cells found in a given program state exceed the value derived from the check sum values, the read verify (RV) threshold value associated with that given program state may be raised or the Read Verify reference level associated with the adjacent higher state may be lowered. Conversely, if the number of cells found in a given program state is below the expected number, either the read verify threshold value associated with the given program state may be lowered, or the read verify threshold value associated with the next higher adjacent state may be raised.

If the number of cells found (read) in a given program state is below an expected value, either the Read Verify reference voltage associated with that given state may be reduced, or if there is found that the number of cells read above the given state exceeds an expected number, the Read Verify reference associated with a logical state higher and adjacent to the given state may be raised. Conversely, if the number of cells found (for example, read) in a given program state is above expectations, either the Read Verify reference voltage associated with that given state may be increased, or if there is found that the number of cells read above the given state is below an expected number, the Read Verify reference associated with a logical state higher and adjacent to the given state may be lowered.

Thus, Read Verify reference voltages for a set of cells may be selected such that the number of cells found/read in each of the states associated with the set may be substantially equal to the number either read from or derived from the values counted during programming of the set of cells, which values may have been stored in a check sum table.

The steps described hereinabove may be repeated as part of an iterative process until the number of cells read in each program state substantially corresponds to the number of cells expected in each state based on data recorded during programming. The process may start with the checking of cells programmed to the highest logical state, or cells programmed to several different states may be checked in parallel.

Generally, when reading memory cells, the correct read verify (RV) voltage (RV) should be such that all of the cells programmed to a Vt higher than the RV voltage (or simply “RV”) should actually have a Vt that is higher than RV. For example, with reference to FIG. 5B,
all of the cells programmed to 01, 00 and 10 should have a threshold voltage higher than RV01,
all of the cells programmed to 00 and 10 should have a threshold voltage higher than RV00, and
all of the cells programmed to 10 should have a threshold voltage higher than RV10.

Then, for example, by subtracting out the number of cells having a threshold voltage above RV10 (which should include only the cells programmed to 01), the number of cells programmed to 00 can be determined.

Using error detection (ED) techniques, the number of cells programmed at each program level is known (it may be counted before or during programming). For example, if 512 cells (or storage areas of NROM cells) are programmed to 00 or 10, during read, there should be 512 cells with Vt greater than RV00.

Generally, when discussing determining the number of cells “at” a given program level, such as for error detection (ED), it should be understood that, in practice, this may be done by determining how many cells have their threshold voltage “at or above” a read value. For example, if there are 4 program levels, separated by three windows, the number of cells which are “at” level 4 can be determined by counting how many cells have a Vt which is above a first read level which is between level 3 and level 4. The number of cells which are “at” level 3 can be determined by counting how many cells have a Vt which is above a second read level which is between level 2 and level 3, which will include the total number of cells at levels 3 and 4. By subtracting the first count (the number of cells determined to be at level 4 from the total number of cells determined to be at level 3 and level 4), the number of cells at level 3 can readily be determined. The number of cells which are “at” level 2 can be determined by counting how many cells have a Vt which is above a third read level which is between level 1 and level 2, which will include the total number of cells at levels 2, 3 and 4. By subtracting out the number of cells determined to be at levels 3 and 4, the number of cells at level 2 can readily be determined. Finally, by knowing the total number (“all”) of cells in the read block, the number of cells at level 1 is simply “all” minus the number of cells determined to be at levels 2, 3 and 4. (All of the cells are at one of the program levels, no cells are “unaccounted for”.)

FIGS. 6A and 6B illustrate a read problem associated with threshold voltage drift, and the general solution. Two (of four) adjacent program states “11” and “01” are illustrated. (State 11 may be “erase”, and the two program states illustrated may be two of the four program states illustrated in FIG. 5B.)

In FIG. 6A, everything is fine. This could represent a freshly programmed memory cell array which has not been subjected to a significant history of program and erase cycles. There is a nice large gap (window) between the two adjacent program levels 11 and 01, RV01 is suitably centered (positioned) between the highest Vt for a cell at 11 and the lowest Vt for a cell at 01, and when reading the contents of the memory cells, the number of cells programmed at each level should agree with the number stored during programming.

In FIG. 6B, the situation has changed. This could represent a block of memory cells that have been subjected to a significant history of program and erase cycles. The threshold voltages for the cells at program level 11 have increased, and the threshold voltages for the cells at program level 01 have decreased. There is now a smaller gap between the two adjacent program levels 11 and 01. More importantly, RV01 is now located within the distribution for 01.

For example, assume that there are supposed to be 512 cells at a program level 01, above RV01, as determined during programming (and stored, for error detection). Using an initial (first guess) value for RV01, it is determined that there are only 435, rather than 512 cells above RV01. Therefore, 77 cells are “missing”, their threshold voltage is below RV01. Therefore, a downward adjustment (shift) must be made to the read value (RV00), in an attempt to find a “corrected” read value RV01′ (prime) which will include the 77 missing cells. This is fundamental to the concept of “moving read reference”.

The example of FIG. 6B illustrates a situation where the subject cells (in this case those cells programmed to 01) have shifted downward, encroaching on their associated read value (RV01). In a case where the threshold voltages for the subject cells shifts upward, they may encroach on the next higher read value (RV00, see FIG. 5B), but the principles applied will be the same.

The example of FIG. 6B illustrates a situation where the distributions for each given range of program values move as a whole. In other words, at a given program level (such as 01), all the cells programmed at that level will shift by a similar amount.

As described in the moving reference patent, after repeated program and erase cycles, the read level (RV, or Vccr_ref or Vccr array) may need to be shifted in order to assess (arrive at) the correct read level. In the moving reference patent, the idea is to do some kind of search for the read location, based on predefined steps. Shifting the read level may be referred to herein as “read positioning”.

In the example of FIG. 6B, 512 bits were programmed to Level “01”, and in a first read attempt, there are 77 missing bits. In the moving reference patent, when such a missing bits error is detected, the read level may be moved in pre-defined steps (for example—200, 100, 50 mv), and after each step, another read is implemented until no bits are missing.

Various other techniques can be employed to find the “missing bits”. Generally, in any error correction technique of this sort an important consideration is “latency”, or how long it is going to take to correct a read problem and obtain valid data. For purposes of this discussion, generally, a read (RD) operation may take 50 μsec (microseconds). Making the decision to shift RV may take 0.1 μsec. If many iterations are required to find a corrected read value, a lot of time can be used. For example, 4 tries (including the initial guess) may take ˜200 μsec. Various factors come into consideration: first of all, determining that there is a read error, such as by using ED bits, and secondly, correcting the read error, such as by shifting RV, as described above.

ED bits may be programmed into multi-level cells in a “high reliable” manner, to reduce problems associated with threshold voltage shift. For example, in cells having 4 accessible program levels, such as shown in FIG. 5B, the ED bits may be programmed using only two widely separated levels, such as “11” (the lowest threshold voltages) and “10” (the highest threshold voltage), so that there is a wide gap between the two threshold voltage distributions, and the ED bits can reliably be read.

Distribution Overlap

In the example described above with respect to FIG. 6B, the threshold voltage of the cells at a given program level (“01”) shifted, generally uniformly, to the left (as viewed) towards a distribution at the next lower program level (“11”), and there is still a window (gap) between the distributions of threshold voltages at the two program levels sufficient for a read value (RV01′) to be found which can be used to distinguish between cells programmed at the two program levels, despite the threshold voltage drift. A situation such as this can be detected by using ED bits, and can be corrected by shifting the read voltage (RV), as described above. Note that the distributions at each level do not overlap (as viewed, the left hand edge of the right distribution “01” is to the right of the right hand edge of the left distribution “11”). However, various retention failures may cause “distribution overlap”.

As relevant to the present disclosure, distribution overlap generally means that there are some cells in a given distribution, such as a lower portion (on a left hand side) of the distribution, which may be at substantially the same threshold voltage as the same threshold voltage as some cells in another distribution, such as a higher portion (on the right hand side) of a lower distribution. This situation is illustrated in FIGS. 7A and 7B.

FIG. 7A illustrates a situation where, initially, the distribution for a number of cells at a first program level (“Level 1”) is separated from the distribution for a number of cells at a second program level (“Level 2”), and the two program levels are nicely separated from one another. Using conventional error detection and moving read, an RV can readily be established which is higher than Level 1 and lower than Level 2, to distinguish between the cells at Level 1 and Level 2, and the RV can be used to accurately read the contents of the cells.

FIG. 7B illustrates a situation where, as a result of a retention failure, the cells at Level 2 have shifted (to the left, representing downward in voltage, see arrow labeled “shift”), and the cells at Level 1 have not similarly shifted, with the result that some of the cells at Level 2 are at the same threshold voltage as some of the cells at Level 1. This is a situation which ED and moving read reference technique (as described above) cannot solve. There is no read level RV which can sort out which of the Levels (1 or 2) the cells in the overlapping area belong to.

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arrays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer. Some examples may be found in commonly-owned U.S. Pat. Nos. 5,966,603, 6,030,871, 6,133,095 and 6,583,007.

Commonly-owned patents also disclose algorithms and methods of operation for each segment or technological application, such as: fast programming methodologies in all flash memory segments, with particular focus on the data flash segment, smart programming algorithms in the code flash and EEPROM segments, and a single device containing a combination of data flash, code flash and/or EEPROM. Some examples may be found in commonly-owned U.S. Pat. Nos. 6,954,393 and 6,967,896.

Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon), TANOS (Tantalum-Nitride-Oxide-Silicon) and the like used for NVM devices. Further description of NVM and related technologies may be found at “Non Volatile Memory Technology”, Vol. 1 & 2 (2005), Vol. 3 (2006) and Vol. 4 (2007), published by Saifun Semiconductor; “Microchip Fabrication”, by Peter Van Zant, 5^{th} Edition 2004; “Application-Specific Integrated Circuits” by Michael John Sebastian Smith, 1997; “Semiconductor and Electronic Devices”, by Adir Bar-Lev, 2^{nd} Edition, 1999; “Digital Integrated Circuits” by Jan M. Rabaey, Anantha Chandrakasan and Borivoje Nikolic, 2^{nd} Edition, 2002 and materials presented at and through http://siliconnexus.com, “Design Considerations in Scaled SONOS Nonvolatile Memory Devices” found at:

http://klabs.org/richcontent/MemoryContent/nvmt_symp/nvmts_{—}2000/presentations/bu_white_sonos_lehigh_univ.pdf, “SONOS Nonvolatile Semiconductor Memories for Space and Military Applications” found at:

http://klabs.org/richcontent/MemoryContent/nvmt_symp/nvmts_{—}2000/papers/adams_d.pdf, “Philips Research—Technologies—Embedded Nonvolatile Memories” found at:

http://www.research.philips.com/technologies/ics/nvmemories/index.html, and “Semiconductor Memory: Non-Volatile Memory (NV” found at:

http://www.ece.nus.edu.sg/stfpage/elezhucx/myweb/NVM.pdf,

all of which are incorporated by reference herein in their entirety.

Glossary

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).

When glossary terms (such as abbreviations) are used in the description, no distinction should be made between the use of capital (uppercase) and lowercase letters. For example “ABC”, “abc” and “Abc”, or any other combination of upper and lower case letters with these 3 letters in the same order, should be considered to have the same meaning as one another, unless indicated or explicitly stated to be otherwise. The same commonality generally applies to glossary terms (such as abbreviations) which include subscripts, which may appear with or without subscripts, such as “X_{yz}” and “Xyz”. Additionally, plurals of glossary terms may or may not include an apostrophe before the final “s”—for example, ABCs or ABC's.

adder In electronics, an adder or summer is a digital circuit that performs addition of numbers.

algorithm In mathematics, computing, linguistics, and related disciplines, an algorithm is a definite list of well-defined instructions for completing a task; that given an initial state, will proceed through a well-defined series of successive states, eventually terminating in an end-state.

array memory cells may optionally be organized in an array of rows and columns, and may be connected to selected bit lines and word lines in the array. The array may be organized into various logical sections containing pluralities of memory cells, such as blocks, pages and sectors. Some of these sections may be physically isolated and operated independently from one another.

associative array An associative array (also associative container, map, mapping, hash, dictionary, finite map, lookup table, and in query-processing an index or index file) is an abstract data type composed of a collection of keys and a collection of values, where each key is associated with one value. The operation of finding the value associated with a key is called a lookup or indexing, and this is the most important operation supported by an associative array. The relationship between a key and its value is sometimes called a mapping or binding. For example, if the value associated with the key “bob” is 7, we say that our array maps “bob” to 7.

BER short for bit error rate. In telecommunication, an error ratio is the ratio of the number of bits, elements, characters, or blocks incorrectly received to the total number of bits, elements, characters, or blocks sent during a specified time interval. The most commonly encountered ratio is the bit error ratio (BER)—also sometimes referred to as bit error rate.

binary system The binary numeral system, or base-2 number system, is a numeral system that represents numeric values using only two symbols, usually “0” and “1”. Owing to its straightforward implementation in electronic circuitry, the binary system is used internally by virtually all modern computers. Many 1s and 0s can be strung together to represent larger numbers. Starting at the right is the “place” for “ones”, and there can be either 0 or 1 one's. The next “place” to the left is for “twos”, and there can be either 0 or 1 0 two's. The next “place” to the left is for “fours”, and there can be either 0 or 1 0 fours. The next “place” to the left is for “eights”, and there can be either 0 or 1 0 eights. This continues for as many places as desired, typically 4, 8, 16, 32 or 64 places.

For example,
0000 represents zero (a “0” in all four places)
0001 represents one (a “1” in the ones place, and 0s in all of the other three places)
0010 represents two (a “1” in the twos place, and 0s in the other three places)
0011 represents three (a “1” in the ones place, plus a “1” in the twos place)
0100 represents four (a “1” in the fours place, and 0s in all of the other three places)
1000 represents eight (a “1” in the eights place, and 0s in all of the other three places)
1010 represents ten (a “1” in the ones place, plus a “1” in the twos place)

In binary notation, each “place” to the left of the first (ones) place has a possible value of either 0 or, if there is a “1” in the place, two times the value of the place immediately to the right. Hence, from right (least significant bit) to left (most significant bit), the places have a value of either 0 or 1, 2, 4, 8, 16, 32, 64, 128, and so forth.

bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of an NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.

BL short for bit line. The bit line is a conductor connected to the drain (or source) of a memory cell transistor.

block code In computer science, a block code is a type of channel coding. It adds redundancy to a message so that, at the receiver, one can decode with minimal (theoretically zero) errors, provided that the information rate (amount of transported information in bits per sec) would not exceed the channel capacity. The main characterization of a block code is that it is a fixed length channel code (unlike source coding schemes such as Huffman coding, and unlike channel coding methods like convolutional encoding). Typically, a block code takes a k-digit information word, and transforms this into an n-digit codeword.

byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be formed using the standard range of prefixes, for example, kilobyte (KB), megabyte (MB) and gigabyte (GB).

cache In computer science, a cache is a collection of data duplicating original values stored elsewhere or computed earlier, where the original data is expensive to fetch (due to longer access time) or to compute, compared to the cost of reading the cache. In other words, a cache is a temporary storage area where, for example, frequently accessed data can be stored for rapid access. Once the data is stored in the cache, future use can be made by accessing the cached copy rather than re-fetching or recomputing the original data, so that the average access time is shorter.

cell the term “cell” may be used to describe anything, such as a NVM cell, that can store one unit of analog data. This includes PG memory cells, and non-FG memory cells, such as NROM. See half cell.

channel coding In computer science, a channel code is a broadly used term mostly referring to the forward error correction code and bit interleaving in communication and storage where the communication media or storage media is viewed as a channel. The channel code is used to protect data sent over it for storage or retrieval even in the presence of noise (errors).

CHE short for channel hot electron. CHE is an “injection mechanism” for injecting electrons into a charge storage area of an NVM memory cell.

CHEI short for channel hot electron injection. sometimes abbreviated “CHE”.

CMOS short for complementary metal oxide semiconductor. CMOS consists of n-channel and p-channel MOS transistors. Due to very low power consumption and dissipation as well as minimization of the current in “off” state, CMOS is a very effective device configuration for implementation of digital functions. CMOS is a key device in state-of-the-art silicon microelectronics.

CMOS Inverter: A pair of two complementary transistors (a p-channel and an n-channel) with the source of the n-channel transistor connected to the drain of the p-channel transistor and the gates connected to each other. The output (drain of the p-channel transistor) is high whenever the input (gate) is low and the other way round. The CMOS inverter is the basic building block of CMOS digital circuits.

NMOS: n-channel CMOS.

PMOS: p-channel CMOS.

comparator In electronics, a comparator is a device which compares two voltages or currents and switches its output to indicate which is larger. More generally, the term is also used to refer to a device that compares two items of data.

complement In many different fields, the complement of “X” is something that, together with “X”, makes a complete whole, something that supplies what “X” lacks. The concept of “complement” has a variety of uses in mathematics and computer science. For example:
(a) a system known as “ones' complement” can be used to represent negative numbers. The ones' complement form of a negative binary number is the bitwise NOT applied to it—the complement of its positive counterpart.
(b) a “two's complement” of a binary number is defined as the value obtained by subtracting the number from a large power of two (specifically, from 2N for an N-bit two's complement).

convolutional code In telecommunication, a convolutional code is a type of error-correcting code in which (a) each m-bit information symbol (each m-bit string) to be encoded is transformed into an n-bit symbol, where m/n is the code rate (n≧m) and (b) the transformation is a function of the last k information symbols, where k is the constraint length of the code.

distribution overlap A number of cells programmed at a given program level may exhibit a distribution of threshold voltages. Usually, the distribution for one program level is separated from a distribution for another program level. However, due to threshold drift, one or both of the distrubutions may move towards the other, causing some of the threshold voltages to be the same. The region where the threshold voltages are the same for cells programmed at two different program levels is the distribution overlap.

disturb When applying a pulse to a specific bit by raising WL and BL voltages, neighboring bits located on the same WL or same BL might suffer from Vt shift that cause margin loss. The shift is called “disturb”. Disturbs are a fault type where the content of a cell is unintentionally altered when operating on another cell. These faults have similar characteristics to coupling faults, however, they have special neighborhood requirements.

Disturb faults are generally caused by the presence of high/intermediate electric field stress on an insulating layer within the core memory cell. This electric field results in leakage current caused either by FN-tunneling, punchthrough, or channel hot electron injection. Whether a given mechanism is responsible for a particular disturb is a function of the operating conditions and the state of the investigated cell.

The IEEE Standard Definition and Characterization of Floating Gate Semiconductor Arrays disturb faults can be divided into the following:

Word-line erase disturb (WED): Exists when a cell under program (selected cell) causes another unprogrammed cell (unselected cell), sharing the same wordline, to be erased.

Word-line program disturb (WPD): Exists when a cell under program (selected cell) causes another unprogrammed cell (unselected cell), sharing the same wordline, to be programmed.

Bit-line erase disturb (BED): Exists when a cell under program (selected cell) causes another unprogrammed cell (unselected cell), sharing the same bit-line, to be erased.

Bit-line program disturb (BPD): Exists when a cell under program (selected cell) causes another unprogrammed cell (unselected cell), sharing the same bitline, to be programmed.

Read disturb (RD): During read operation, the bias conditions are the same as programming conditions (except for lower voltage magnitudes) and can result in the injection of electrons from drain to FG thus programming the selected cell. This is known as a soft program. In addition, unselected erased cells may become programmed, and those that are programmed may become erased, giving rise to what is known as gate read erase and channel read program, respectively. Both of these disturbs that occurs on un-addressed cells are considered to be another form of read disturbs.

ECC short for error correcting code. An error-correcting code (ECC) is a code in which each data signal conforms to specific rules of construction so that departures from this construction in the received signal can generally be automatically detected and corrected. It is used in computer data storage, for example in dynamic RAM, and in data transmission.

Some codes can correct a certain number of bit errors and only detect further numbers of bit errors. Codes which can correct one error are termed single error correcting (SEC), and those which detect two are termed double error detecting (DED). Hamming codes can correct single-bit errors and detect double-bit errors—SEC-DED. More sophisticated codes correct and detect even more errors.

An error-correcting code which corrects all errors of up to n bits correctly is also an error-detecting code which can detect at least all errors of up to 2n bits.

Two main categories are convolutional codes and block codes. Examples of the latter are Hamming code, BCH code, Reed-Solomon code, Reed-Muller code, Binary Golay code, and low-density parity-check codes.

ED bits as used herein, ED bits are numbers which may be calculated for and stored along with data being programmed (stored), which are indicative of the number of cells (or half-cells) at any given program level, for example, 512 cells (or half cells) at program level “10”. During a subsequent read operation, the ED bits may be retrieved along with the data which was stored, the number of cells at the given program levels are counted, and these counts are compared with the ED bits. If there is a mismatch, this indicates a read error, and an error correction scheme such as “moving read reference” can be implemented. See moving read reference.

EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and, more typically, a full Page. While an erase and rewrite of a location appears nearly instantaneous to the user, the write process is usually slightly slower than the read process; the chip can usually be read at full system speeds.

endurance Because they are written by forcing electrons through a layer of electrical insulation onto a floating gate (or charge trapping medium), some NVM can withstand only a limited number of write and erase cycles before the insulation is permanently damaged, and the ability of the cell to function correctly is compromised. In modern Flash EEPROM, the endurance may exceed 1,000,000 write/erase cycles.

EPROM short for erasable, programmable read only memory. EPROM is a memory cell in which information (data) can be erased and replaced with new information (data).

erase a method to erase data on a large set of bits in the array, by applying a voltage scheme that injects holes in the bit set. This method causes all bits to reach a low Vt level. See program and read.

Error Detection and Correction In computer science, telecommunication, and information theory, error detection and correction has great practical importance in maintaining data (information) integrity across noisy channels and less-than-reliable storage media. More particularly,
Error detection is the ability to detect the presence of errors caused by noise or other impairments during transmission from the transmitter to the receiver.
Error correction is the additional ability to reconstruct the original, error-free data.

FEC short for forward error correction. In telecommunication, forward error correction (FEC) is a system of error control for data transmission, whereby the sender adds redundant data to its messages, which allows the receiver to detect and correct errors (within some bounds), without the need to ask the sender for additional data. The advantage of forward error correction is that retransmission of data can often be avoided, at the cost of higher bandwidth requirements on average, and is therefore applied in situations where retransmissions are relatively costly or impossible.

FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.

VG short for floating gate. The floating-gate transistor is a kind of transistor that is commonly used for non-volatile storage such as flash, EPROM and EEPROM memory. Floating-gate transistors are almost always floating-gate MOSFETs. Floating-gate MOSFETs are useful because of their ability to store an electrical charge for extended periods of time even without a connection to a power supply.

Flash memory Flash memory is a form of non-volatile memory (EEPROM) that can be electrically erased and reprogrammed. Flash memory architecture allows multiple memory locations to be erased or written in one programming operation. Two common types of flash memory are NOR (“Not Or”) and NAND flash. NOR and NAND flash get their names from the structure of the interconnections between memory cells. In NOR flash, cells are connected in parallel to the bit lines, allowing cells to be read and programmed individually. The parallel connection of cells resembles the parallel connection of transistors in a CMOS NOR gate. In NAND (“Not And”) flash, cells are connected in series, resembling a NAND gate, and preventing cells from being read and programmed individually: the cells connected in series must be read in series.

flip-flop In electronics, an electronic circuit which has two stable states and thereby is capable of serving as one bit of memory. A flip-flop is usually controlled by one or two control signals and/or a gate or clock signal. The output often includes the complement as well as the normal output. As flip-flops are implemented electronically, they naturally also require power and ground connections.

FN tunneling Field emission—also called Fowler-Nordheim tunneling—is the process whereby electrons tunnel through a barrier in the presence of a high electric field. This quantum mechanical tunneling process is an important mechanism for thin barriers such as those in metal-semiconductor junctions on highly-doped semiconductors. Using FN tunneling, electrons can be moved to the floating gate of a MOSFET memory cell.

Gray code The reflected binary code, also known as Gray code after Frank Gray, is a binary numeral system where two successive values differ in only one digit. The reflected binary code was originally designed to prevent spurious output from electromechanical switches. Today, Gray codes are widely used to facilitate error correction in digital communications. An example of a two-bit binary Grey code sequence is 00, 01, 11, 10. An example of a three-bit binary Grey code sequence is 000, 001, 011, 010, 110, 111, 101, 100.

half cell “half cell” (or “half-cell”) is a term which is sometimes used to refer to the two distinct charge storage areas (left and right bits) of an NROM memory cell.

Hamming code In telecommunication, a Hamming code is a linear error-correcting code named after its inventor, Richard Hamming. Hamming codes can detect and correct single-bit errors. In other words, the Hamming distance between the transmitted and received code-words must be zero or one for reliable communication. Alternatively, it can detect (but not correct) up to two simultaneous bit errors. In contrast, the simple parity code cannot correct errors, nor can it be used to detect more than one error (such as where two bits are transposed).

HHI short for hot hole injection. HHI is an “injection mechanism” for injecting holes into a charge storage area of an NVM memory cell. See CHE.

Information theory Information theory is a branch of applied mathematics and engineering involving the quantification of information. Historically, information theory developed to find fundamental limits on compressing and reliably communicating data. A key measure of information that comes up in the theory is known as information entropy, which is usually expressed by the average number of bits needed for storage or communication. Intuitively, entropy quantifies the uncertainty involved in a random variable. For example, a fair coin flip will have less entropy (2 possible outcomes) than a roll of a die (6 possible outcomes).

Inhibit if it is desired to apply erase to a subset of bits, avoiding erase from other bits sharing the same bit lines (BLs), an inhibit signal may be applied on the others, for example as a positive voltage on the gate, to avoid hole injection. This procedure is called inhibit.

LDPC short for low-density parity check. In information theory, a low-density parity-check code (LDPC code) is an error correcting code, a method of transmitting a message over a noisy transmission channel. While LDPC and other error correcting codes cannot guarantee perfect transmission, the probability of lost information can be made as small as desired. LDPC was the first code to allow data transmission rates close to the theoretical maximum, the Shannon Limit. See, for example, the article “LDPC: Another Key Step Toward Shannon, New low-density parity check (LDPC) error correction techniques push wireless and networking channel performance closer to the Shannon Limit. Here's How.”, by Tony Summers, Comtech AHA Corporation, Oct. 14, 2004, incorporated by reference herein.

logical operators A logical connective, also called a truth-functional connective, logical operator or propositional operator, is a logical constant which represents a syntactic operation on a sentence, or the symbol for such an operation that corresponds to an operation on the logical values of those sentences. A logical connective serves to return (results in) a “true” or “false” value (such as binary “0” or binary “1”) when applied to arguments (operators) also having true or false values. For example, some common logical operators are:
AND the AND operator results in a value of “true” only if both of the operands (A,B) has a value of “true”. (In binary terms, if A=“1” and B=“1”, then the result is “1”. Otherwise, the result is “0”.)
OR the OR operator results in a value of “true” if one or the other, or both of the operands (A,B) has a value of “true”. (In binary terms, if either one of A or B=“1” and B=“1”, the result is “1”. Otherwise, the result is “0”.)
XOR short for exclusive “or”. the XOR operator results in a value of “true” if and only if exactly one of the operands (A,B) has a value of “true”. (In binary terms, if only one of A or B=“1” and B=“1”, the result is “1”. Otherwise, the result is “0”.)

MLC short for multi-level cell. In the context of a floating gate (FG) memory cell, MLC means that at least two bits of information can be stored in the memory cell. In the context of an NROM memory cell, MLC means that at least four bits of information can be stored in the memory cell—at least two bits in each of the two charge storage areas.

MOS short for metal oxide semiconductor.

MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).

moving read reference as used herein, “moving read reference” (or “moving reference”) refers to a technique, such as disclosed in U.S. Pat. No. 6,992,932 wherein reference voltages are determined to be used in reading cells programmed to a given program state. Generally, if an error is detected, such as by using error detection (ED) bits, the reference voltages may have to be adjusted until the error is resolved. See ED bits.

multiplexer In electronics, a multiplexer or mux is a device that performs multiplexing: it selects one of many analog or digital data sources and outputs that source into a single channel.

nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of an NVM memory cell having an ONO layer, as a charge-trapping material.

n-type semiconductor in which concentration of electrons is higher than the concentration of “holes”. See p-type.

NROM short for nitride(d) read only memory. Generally, a FET-type device having a charge trapping medium such as a nitride layer for storing charges (electrons and holes) in two discrete areas, near the source and drain diffusions, respectively.

NVM short for non-volatile memory. NVM is computer memory that can retain the stored information even when not powered. Examples of non-volatile memory include read-only memory, flash memory, most types of magnetic computer storage devices (for example hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of non-volatile memory have limitations which make it unsuitable for use as primary storage. Typically non-volatile memory either costs more or performs worse than volatile random access memory. (By analogy, the simplest form of an NVM memory cell is a simple light switch. Indeed, such a switch can be set to one of two (binary) positions, and “memorize” that position.) NVM includes floating gate (FG) devices and NROM devices, as well a devices using optical, magnetic and phase change properties of materials.

ONO short for oxide-nitride-oxide. ONO is used as a charge storage insulator consisting of a sandwich of thermally insulating oxide, and charge-trapping nitride.

over-erase a condition that happens to some bits in a large bit set that are erased together, due to erase speed difference, due to the situation that some bits erase faster than other bits. Fast bits are particularly susceptible to over-erase. See erase.

oxide commonly used to refer to silicon dioxide (SiO2). Also known as silica. SiO2 is the most common insulator in semiconductor device technology, particularly in silicon MOS/CMOS where it is used as a gate dielectric (gate oxide); high quality films may be obtained by thermal oxidation of silicon.

poly short for polycrystalline silicon (Si). Heavily doped poly Si is commonly used as a gate contact in silicon MOS and CMOS devices.

p-type semiconductor in which concentration of “holes” is higher than the concentration of electrons. See n-type. Examples of p-type silicon include silicon doped (enhanced) with boron (B), Indium (In) and the like.

page Generally, a grouping of memory cells can be termed a word, a grouping of words can be termed a page, and a grouping of pages can be termed a sector. Data may be accessed for reading and programming (or writing) by word or by page, while an entire sector is commonly accessed for erasing.

PFROM short program flashROM. An inner design block (of Saifun) that stores instructions that the inner embedded microcontroller performs on flash devices.

program a method to program a bit in an array, by applying a voltage scheme that injects electrons. This method causes an increase in the Vt of the bit that is being programmed. Alternatively, with “high Vt erase”, programming may be a lowering of the Vt of the memory cell. See erase and read. Program may sometimes, erroneously be referred to as “write”. See write.

program rate as used herein, “program rate” refers to the number of times that a memory cell (or half cell) is programmed to various program (or threshold voltage) levels, such as representing a binary “1” or “0”.

Program time refers to the duration of a single program pulse, or the duration of the whole program sequence algorithm to program a bit set.

programmed “programmed” generally means that the threshold voltage (Vt) of a cell is above a predetermined “program verify” level (Vth).

PROM short for programmable read-only memory.

RAM short for random access memory. RAM refers to data storage formats and equipment that allow the stored data to be accessed in any order—that is, at random, not just in sequence. In contrast, other types of memory devices (such as magnetic tapes, disks, and drums) can access data on the storage medium only in a predetermined order due to constraints in their mechanical design.

read a method to read the digital data stored in the array. The read operation is usually performed in “blocks” of several cells. See erase and program.

Reed-Solomon Reed-Solomon error correction is an error-correcting code that works by oversampling a polynomial constructed from the data. The polynomial is evaluated at several points, and these values are sent or recorded. By sampling the polynomial more often than is necessary, the polynomial is over-determined. As long as “many” of the points are received correctly, the receiver can recover the original polynomial even in the presence of a “few” bad points.

refresh a part of the program or erase algorithms that checks the status of bits and applies pulses to bits that may have lost some of their Vt due to reliability margin loss.

register In electronics, a register is a small amount of storage whose contents can be accessed more quickly than storage available elsewhere. Registers are normally measured by the number of bits they can hold, for example, an “8-bit register” or a “32-bit register”. Registers are now usually implemented as a register file, but they have also been implemented using individual flip-flops.

retention Retention generally refers to the ability of a memory cell to retain charges inserted into the charge storage medium, such as a floating gate. The data retention of EPROM, EAROM, EEPROM, and Flash may be limited by charge leaking from the floating gates of the memory cell transistors. Leakage is exacerbated at high temperatures or in high-radiation environments.

ROM short for read-only memory.

scientific notation Scientific notation, also known as standard form, is a notation for writing numbers that is often used by scientists and mathematicians to make it easier to write large and small numbers. A number that is written in scientific notation has several properties that make it very useful to scientists.

The basic concept for the practical notations is this mathematical exponential expression using powers of ten, for example: a×10^{b} (“a” times ten raised to the “b”th power).

“E notation” is related to, and a form of scientific notation. Most calculators and many computer programs present very large and very small results in scientific notation. Because exponents like 10⁷ (ten to the seventh power) cannot always be conveniently represented on computers, typewriters, and calculators, an alternate notation, “E notation” is often used: the letter “E” or “e” is used for “times ten raised to the power”, with all numbers being written on the same line, without superscripts, for example “3×10¹³”, (three times 10 to the 13^{th} power, or a “11, followed by 12 zeroes) would be written as “3E13”.

sector a part of the array, usually larger than a page, which usually contains a few pages. A minimum erase might include a sector. For example:
Erase Sector (ES): Group of cells that are erased by single erase command
Physical Sector (PS): Group of ES connected by single grid of Word Lines (WL) and Bit Lines (BL), sharing same set of drivers.

Shannon Limit Information theory is generally considered to have been founded in 1948 by Claude Shannon in his seminal work, “A Mathematical Theory of Communication” The Bell System Technical Journal, Vol. 27, pp. 379-423, 623-656, July, October 1948, herein incorporated by reference in its entirety. The central paradigm of classical information theory is the engineering problem of the transmission of information over a noisy channel. The most fundamental results of this theory are Shannon's source coding theorem, which establishes that, on average, the number of bits needed to represent the result of an uncertain event is given by its entropy; and Shannon's noisy-channel coding theorem, which states that reliable communication is possible over noisy channels provided that the rate of communication is below a certain threshold called the channel capacity. The channel capacity can be approached by using appropriate encoding and decoding systems.

Shannon's theorem is an important theorem in error correction which describes the maximum attainable efficiency of an error-correcting scheme versus the levels of noise interference expected. In general, these methods put redundant information into the data stream following certain algebraic or geometric relations so that the decoded stream, if damaged in transmission, can be corrected. The effectiveness of the coding scheme is measured in terms of code rate, which is the code length divided by the useful information, and the Coding gain, which is the difference of the SNR levels of the uncoded and coded systems required to reach the same BER levels. Shannon's noisy-channel coding theorem states that reliable communication is possible over noisy channels provided that the rate of communication is below a certain threshold called the channel capacity, or “Shannon Limit”.

Si Silicon, a semiconductor.

SLC short for single level cell. In the context of a floating gate (FG) memory cell, SLC means that one bit of information can be stored in the memory cell. In the context of an NROM memory cell, SLC means that at least two bits of information can be stored in the memory cell.

SNR short for signal-to-noise ratio. SNR (often abbreviated SNR or S/N) is an electrical, engineering concept, also used in other fields (such as scientific measurements, biological cell signaling and oral lore), defined as the ratio of a signal power to the noise power corrupting the signal. In less technical terms, signal-to-noise ratio compares the level of a desired signal (such as music) to the level of background noise. The higher the ratio, the less obtrusive the background noise is.

SONOS Si-Oxide-Nitride-Oxide-Si, another way to describe ONO with the Si underneath and the Poly gate on top.

SRAM short for static random access memory. SRAM is a type of semiconductor memory. The word “static” indicates that the memory retains its contents as long as power remains applied, unlike dynamic RAM (DRAM) that needs to be periodically refreshed (nevertheless, SRAM should not be confused with read-only memory and flash memory, since it is volatile memory and preserves data only while power is continuously applied). SRAM should not be confused with SDRAM, which stands for synchronous DRAM and is entirely different from SRAM, or with pseudostatic RAM (PSRAM), which is DRAM configured to function, to an extent, as SRAM.

standard deviation In probability and statistics, the standard deviation of a probability distribution, random variable, or population or multi-set of values is a measure of the spread of its values. It is usually denoted with the letter a (lower case sigma). It is defined as the square root of the variance.

To understand standard deviation, keep in mind that variance is the average of the squared differences between data points and the mean. Variance is tabulated in units squared. Standard deviation, being the square root of that quantity, therefore measures the spread of data about the mean, measured in the same units as the data.

Said more formally, the standard deviation is the root mean square (RMS) deviation of values from their arithmetic mean.

The standard deviation is a measure of statistical dispersion. In plain English it's a way of describing how spread out a set of values are around the mean of that set.

For example, if you have a set of height measurements, you can easily work out the arithmetic mean Oust sum up all the individual height measurements and then divide by the number of those measurements). However, knowing the mean (or average, as it's more commonly called), doesn't tell you about the spread of those heights. Were all the people in your group the same height, or did you have some tall and some short, or was there one really tall person who towered over everybody else? It's possible that you could have exactly the same average height from wildly different groups. Knowing about how spread out those heights are compared to the mean gives you extra information over and above the mean value.

Units of Length Various units of length may be used herein, as follows:
meter (m) A meter is the SI unit of length, slightly longer than a yard.
   1 meter=˜39 inches. 1 kilometer (km)=1000 meters=˜0.6 miles.
   1,000,000 microns=1 meter. 1,000 millimeters (mm)=1 meter.
   100 centimeters (cm)=1 meter.
micron (μm) one millionth of a meter (0.000001 meter); also referred to as a micrometer.
mil 1/1000 or 0.001 of an inch; 1 mil=25.4 microns.
nanometer (nm) one billionth of a meter (0.000000001 meter).
Angstrom (Å) one tenth of a billionth of a meter. 10 Å=1 nm.

verify a read operation after applying a program or erase pulse, that checks if the applied program or erase pulse moved the Vt to the target level (program-verify or erase-verify level).

V short for voltage. Different voltages may be applied to different parts of a transistor or memory cell to control its operation, such as:
Vb short for bulk (or substrate) voltage
Vd short for drain voltage
Vg short for gate voltage
Vs short for source voltage
Vt short for threshold voltage

wear leveling Wear levelling (also written wear leveling) refers to a technique for prolonging the service life of some kinds of erasable computer storage media, such as flash memory. EEPROM and flash memory media have individually erasable segments, each of which can be put through a finite number of erase cycles before becoming unreliable. This can be anywhere between 10,000 and 1,000,000 cycles, for example, for NAND flash devices. Wear-levelling attempts to work around these limitations by arranging data so that erasures and re-writes are distributed evenly across the medium. In this way, no single sector prematurely fails due to a high concentration of write cycles.

word line or wordline, (WL). A conductor normally connected to the gate of a memory cell transistor. The wordline may actually be the gate electrode of the memory cell.

write a combined method usually involving first erasing a large set of bits, then programming new data into the bit set; the erase step is not required but it is customary. See erase and program.

In addition to the above, some abbreviations or terminology that may be used herein, or in a provisional application (if any) from which this non-provisional application claims priority, may include:

addr short for adder

bpc, b/c, [b/c] short for bits per cell (or half-cell, depending on context)

comp short for comparator

DPM short for defects per million

ECC short for error correction code

ED short for error detection

FF short for flip-flop

IECC short for internal error correction

LSB short for least significant bit

MSB short for most significant bit

mux short for multiplexer

OTP short for one time programmable

Rd short for read

sigma bits a type of error correction bits, the derivation and use of which is explained in this disclosure

### SUMMARY

An object of the disclosure is to provide improved techniques for error correction for determining the level at which cells (or half-cells) are programmed, in a non-volatile memory (NVM) array.

In the main, hereinafter, “cells” are referred to, and this should be understood to include “half-cells”, such as in NROM memory devices that have two charge-trapping areas, or two “half-cells” per device. The techniques disclosed herein are also applicable to floating gate (FG) memory “cells”.

Generally, the techniques disclosed herein are applicable to single level programming (“1” or “9”) of a given cell (or half-cell), as well as multi-level programming (such as the four levels “00”, “01”, “10”, “11”) of a given cell (or half-cell).

Generally, before bits are written to an NVM array, they are temporarily stored (or buffered) in an SRAM.

Generally, the error detection technique disclosed herein can be used for “sorting out” bits (more generally, the Vt of cells) from two adjacent program levels which have threshold voltages (Vt's) that overlap each other. In other words, some of the bits (or cells) from a given program level distribution may have a low Vt which is in the range of the higher Vt bits of a lower program level distribution. This may occur from threshold voltage drift, and is illustrative of what may generally be termed a “retention” problem.

The techniques disclosed herein enable effective retention and reliability improvement. Using the techniques disclosed herein, distributions overlap phenomena, which commonly occur on NVM, can be reduced, corrected, or completely fixed.

The techniques disclosed herein can find the errors and output the correct data outside to the user. It depends on the Flash chip designer whether to use the algorithm correction and separate the distributions from overlap, or keep it this way (in both cases the user will get reliable data). The actual correction of Vts depend on the decision of the Flash chip designer (in other words, the correction output of the algorithm can be used to correct Vts). If the block has shifted dramatically, it is recommended that this (correcting the Vts) should be done.

Generally, in cases where the BER (Bit Error Rate) is too high, it is not practical to use an external ECC controller. By using the techniques disclosed herein, the BER can be reduced (brought to lower values). If, using the techniques disclosed herein, the errors are not completely fixed, they may be reduced to a level such that it is practical to correct the remaining errors using an external ECC controller.

Since the techniques disclosed herein can effectively sort out distribution overlaps, they can also be used to increase the number of distributions on a product and therefore produce more storage bits per flash cell. In other words, in one aspect, the techniques can be used to fix problems, such as sorting out bits in distributions which were initially programmed in separate and distinct distributions but which, due to threshold voltage shift, have become overlapping. And, in another aspect, the techniques disclosed herein allow programming with advertent overlapping distributions, and the bits can nevertheless be sorted out.

The techniques disclosed herein provide an approach to fix (or reduce) the errors in the inner (on-chip) flash before it gets to an external controller. By detecting a small number of “suspected” half-cells which contains all errors among them, the errors can be determined by a mathematical calculation. Advantages may include, but are not limited to:
Low cost with high performance
Not dependent on an external controller
Using internal chip read results to defined suspected cells (or half-cells)
Retention and reliability improvement
Potential for future development of increased (such as double) storage per cell (such as by programming with overlapping threshold voltage distributions)

Generally, the technique works as follows,
while programming data to NVM, a sum of indexes of all half-cells above (or at) some program level is calculated and programmed. Mathematical operators other than “sum” may be used. The indexes mentioned here are related to a temporary storage address for the data, such as in SRAM.
when reading the data, “suspected” half-cells can be marked, which contains all errors among them.
the number of errors can be calculated
with the sum of indexes determined during programming, suspected cells and number of errors, a combination can be found among the suspected cells which sums to the sum of indexes, and therefore solves distribution overlap.

According to an embodiment of the disclosure, a method of operating non-volatile memory (NVM) array comprises: during programming, calculating sigma bits for cells storing data at each program level based on attributes of the cells at the program level and storing the sigma bits in the memory array along with data. A sigma bit may be based on an index representing a cell's bit location in the memory array, and the index may be based on a temporary cache storage address for the bits being programmed into the memory array. Calculating sigma bits may comprise a mathematical operation on indexes for the cells at each program level, wherein the mathematical operation is selected from the group consisting of: summing the indexes; a XOR operation on rd-chunk's data; rotation of a known vector; multiplication of indexes; bit-wise operation; and different weight of indexes. The indexes may be assigned with an increasing weight factor, such as factor-of-2.

During read, new sigma bits may be calculated for the stored data. By comparing the new sigma bits to the stored sigma bits, a read error may be declared when the new sigma bits differ from the stored sigma bits. A difference between the new sigma bits and the stored sigma bits may define a unique combination of indexes, enabling searching for, finding and correcting the read errors.

By using the techniques disclosed herein, during read, the sigma bits may be used to correctly identify which cells were programmed at which program level, despite threshold voltage drift and/or overlap.

According to a feature of the disclosure, ED bits may be used in conjunction with the sigma bits during a read operation to correctly identify which cells (or half-cells) were programmed at which program level.

According to a feature of the disclosure, the sigma bits may define a unique combination of indexes, enabling searching for, finding and correcting read errors.

When the sigma bits are based on indexes for the cells storing data, the indexes may be assigned in a manner to provide substantially unique index combinations for bits at the different program levels. An incremental series of indexes may be used.

According to an aspect of the disclosure, during read, new sigma bits may be calculated for the stored data and by comparing the new sigma bits to the stored sigma bits; a list of suspect cells that may contain read errors may be defined, such as by using ED bits, and the list of suspect cells may be used to identify a unique combination that brings the calculated sigma bits into agreement with the stored sigma bits. The suspect cells may be located using a moving read reference. A list of suspect cells may comprise cells in two program level distributions that have overlapping threshold voltages.

According to an embodiment of the disclosure, a method of programming data in non-volatile memory (NVM) comprises: programming a chunk of data in a plurality of cells of a memory array; programming ED bits along with the data, wherein the ED bits are indicative of how many cells have been programmed at each program level; and programming sigma bits along with the data, wherein the sigma bits are indicative of attributes of the cells where the data is programmed. When reading the chunk of data, the programmed ED bits and sigma bits may also be read. The data may be programmed in at least two distributions, one of which is a right distribution, the other of which is a left distribution; and a first read may be done with a read reference (rd1) closer to the right distribution to ensure that no bits from the left distribution are read with errors.

According to a feature of the disclosure, a suspects table may be initialized. ED bits may be calculated for the chunk of data being read and, if the calculated ED bits do not agree with the stored ED bits, then the read reference may be moved and reading repeated until the calculated ED bits agree with programmed ED bits, or until maximum of number of read fixes is reached; and, after each read, updating the suspects table. A best combination of indexes may be found from the suspects table suspected half-cells that completes the sum of indexes (or other mathematical operator) of a program-level to its sigma bits.

According to an embodiment of the disclosure, a method of operating non-volatile memory (NVM) array comprising: programming different program levels with overlapping threshold voltage distributions and, when reading, sorting out bits programmed at the different program levels and having overlapping threshold voltages.

The techniques disclosed herein may be applicable to most NVM devices including, but not limited to, charge-trapping devices such as NROM (sometimes referred to as Nitride Read Only Memory), SONOS (Semiconductor Oxide Nitride Oxide Semiconductor; Silicon-Oxide-Nitride-Oxide-Silicon), SANOS (Silicon-Aluminum Oxide-Nitride-Oxide-Silicon), MANOS (Metal-Aluminum Oxide-Nitride-Oxide-Silicon), and TANOS (Tantalum-Aluminum Oxide-Nitride-Oxide-Silicon), and also to Floating Gate (FG) devices.

### BRIEF DESCRIPTION OF THE DRAWING(S)

Reference will be made in detail to embodiments of the disclosure, examples of which may be illustrated in the accompanying drawing figures (FIGS). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element). It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, and so forth. Such relationships, if any, between similar elements in the same or different figures will become apparent throughout the specification, including, if applicable, in the claims and abstract.

Throughout the descriptions set forth in this disclosure, lowercase numbers or letters may be used, instead of subscripts. For example Vg could be written V_{g}. (Generally, lowercase is preferred to maintain uniform font size.) Regarding the use of subscripts (in the drawings, as well as throughout the text of this document), sometimes a character (letter or numeral) is written as a subscript—smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H2O”.

Conventional electronic components may be labeled with conventional schematic-style references comprising a letter (such as A, C, Q, R) indicating the type of electronic component (such as amplifier, capacitor, transistor, resistor, respectively) followed by a number indicating the iteration of that element (such as “1” meaning a first of typically several of a given type of electronic component). Components such as resistors and capacitors typically have two terminals, which may be referred to herein as “ends”. In some instances, “signals” are referred to, and reference numerals may point to lines that carry said signals. In the schematic diagrams, the various electronic components are connected to one another, as shown. Usually, lines in a schematic diagram which cross over one another and where there is a dot at the intersection of the two lines are connected with one another, else (if there is no dot at the intersection) they are typically not connected with one another.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4A is a diagram of a memory cell array with NROM memory cells, according to the prior art.

FIG. 4B is a diagram illustrating a technique for operating an NVM array, according to the prior art.

FIG. 5A is a diagram illustrating threshold voltage distributions for memory cells (or half-cells) programmed at two different program levels, according to the prior art.

FIG. 5B is a diagram illustrating threshold voltage distributions for memory cells (or half-cells) programmed at four different program levels, according to the prior art.

FIG. 6A is a diagram illustrating threshold voltage distributions for memory cells (or half-cells) programmed at two (of four) different program levels, according to the prior art.

FIG. 6B is a diagram illustrating threshold voltage distributions for the memory cells (or half-cells) of FIG. 6A, after a threshold voltage shift, according to the prior art.

FIG. 7A is a diagram illustrating threshold voltage distributions for memory cells (or half-cells) programmed at two different program levels, according to the prior art.

FIG. 7B is a diagram illustrating threshold voltage distributions for the memory cells (or half-cells) of FIG. 7A, after a threshold voltage shift, according to the prior art.

FIG. 8 is a diagram illustrating finding suspect cells (or half-cells) resulting from a threshold voltage shift, according to the disclosure.

FIG. 9 is a diagram illustrating a hardware implementation of a calculation unit, according to the disclosure.

FIG. 10A is a diagram illustrating threshold voltage distributions for memory cells (or half-cells) programmed at two different program levels, according to the disclosure.

FIG. 10B is a diagram illustrating threshold voltage distributions for the memory cells (or half-cells) of FIG. 10A, after a threshold voltage shift, and including escape errors, according to the disclosure.

FIG. 10C is a diagram illustrating a technique for finding escape errors, according to the disclosure.

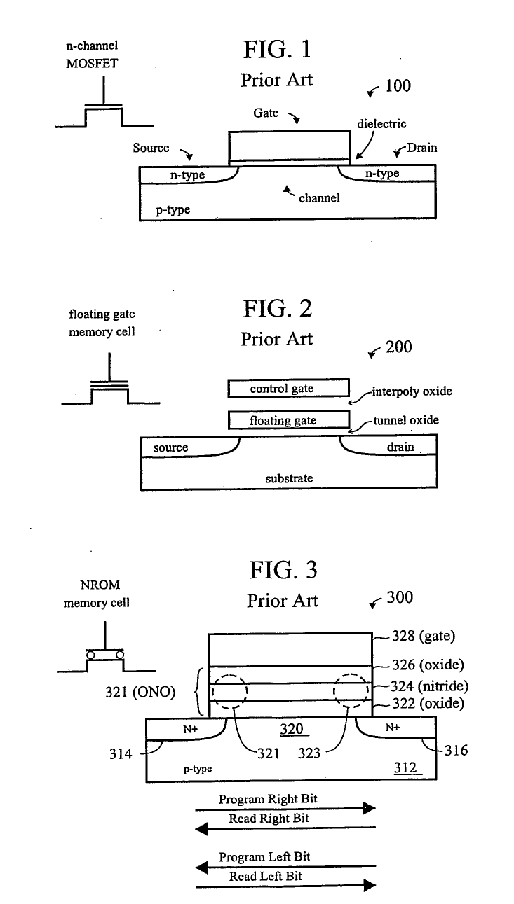

### DETAILED DESCRIPTION

In the following description, various aspects of techniques for correcting errors will be described. For the purpose of explanation, specific configurations and details are set forth in order to provide a thorough understanding of the techniques. However, it will also be apparent to one skilled in the art that the techniques may be practiced without specific details being presented herein. Furthermore, well-known features may be omitted or simplified in order not to obscure the description(s) of the techniques.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification, discussions utilizing terms such as processing, computing, calculating, determining, or the like, refer to the action or processes of a computer or computing system, or similar electronic computing device, that manipulate or transform data represented as physical, such as electronic, quantities within the registers or memories of the computing system into other data similarly represented as physical quantities within the memories, registers or other such information storage, transmission or display devices of the computing system.

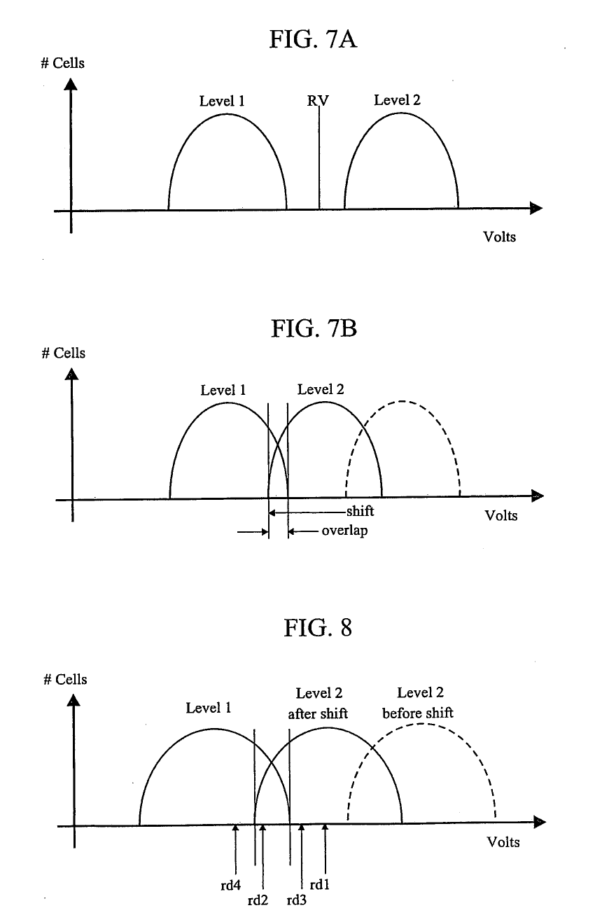

Distribution overlap is described hereinabove, with respect to FIGS. 7A and 7B, and is typically considered to be a problem which is commonly solved today by an external ECC controller, which provides relatively poor results with high cost. Known methods are Reed-Solomon and DLPC. In cases where the BER (Bit Error Rate) is too high, an external ECC controller generally cannot solve the problem.

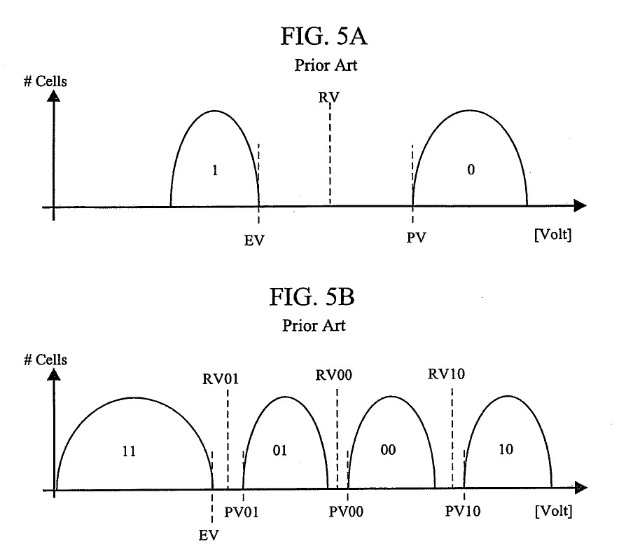

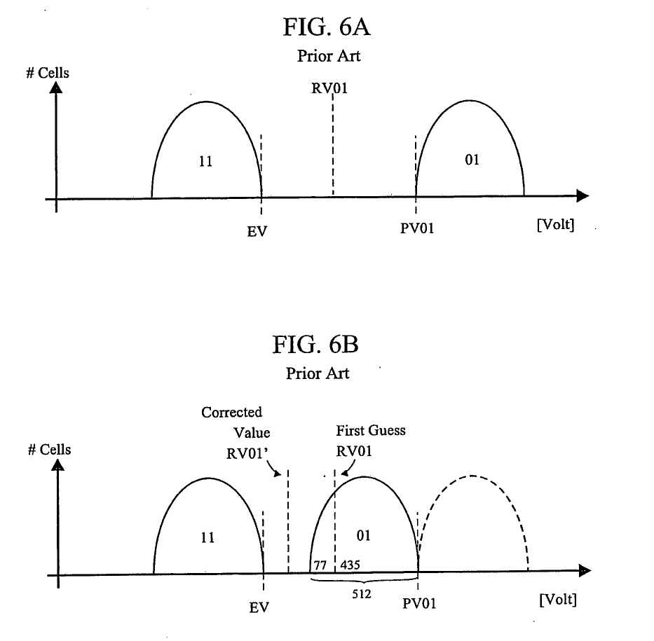

By way of review, FIG. 7B illustrates a situation where a distribution of threshold voltage levels for one group of bits (cells), programmed to be at program level 2 (“Level 2”) have shifted to the left (downwards in voltage) to the extent that some of the Level 2 cells have a threshold voltage which coincides with (overlaps) the threshold voltages of some of the bits programmed at a lower threshold voltage representing program level 1 (“Level 1”). Conventional techniques of moving a read reference to find bits whose threshold voltages have shifted are inadequate for sorting out this situation where bits at two different program levels have the same threshold voltage. In FIG. 7B, the pre-shift distribution for Level 2 is shown in dashed lines, the shift (to the left) is indicated, and the overlap area between the two distributions is illustrated. This is generically illustrative of “distribution overlap”, and it is also possible that the lower voltage distribution (Level 1) shifts upwards to overlap into Level 2. With many (such as four or more) program levels (see for example FIG. 5B), the overlap situation can occur between any two (typically, but not necessarily) adjacent program levels.

According to the techniques disclosed herein, bits originally programmed to be in distributions which were nicely separated, but which became overlapping, can be identified (sorted out). This can be considered to be the “error correction” face of the techniques disclosed herein. It should be understood that the techqniques can also be used in conjuntion with programming bits into distributions which are advertently overlapping, thereby potentially increasing the storage capability of the NVM (more program levels can be stored).

### An Embodiment

According to the disclosure, techniques are provided for determining which cells belong to which program level, even in the case of overlap (“overlap” is graphically illustrated and described with respect to FIGS. 7A and 7B).

It will also become apparent that some bits may experience a threshold voltage shift which is beyond the overlap area, and techniques for finding these “escaping” bits are also discussed hereinbelow.

Generally, “overlap” may be a situation where the threshold voltages (Vt) of memory cells originally programmed with distinctive Vt's (at different program levels, in different Vt distributions) have changed, which may be as a result of “disturb” (operation of other memory cells having an effect on a given, otherwise quiescent memory cell), as a result of which some memory cells from different program levels have threshold voltages which are indistinguishable from one another based on straightforward reading techniques, including moving read reference. It should be understood that the techniques disclosed herein for “sorting out” cells with overlapping threshold voltages into their appropriate (as programmed) program levels may also be applied when the program levels are advertently overlapping, which may allow for more program levels (distributions of threshold voltage) in a given range of threshold voltages.

In the description that follows, techniques relating to cells (or half-cells) at various program levels within a given rd-chunk are discussed. An rd-chunk may be, for example, 512 cells (or half-cells).

Error Detection (ED) bits, which are generally the number of bits at a given program level within the rd-chunk, and known techniques for employing ED bits to perform a valid read despite threshold voltage drift (such as described in the moving read reference patents) may also be used in conjunction with the techniques described herein.

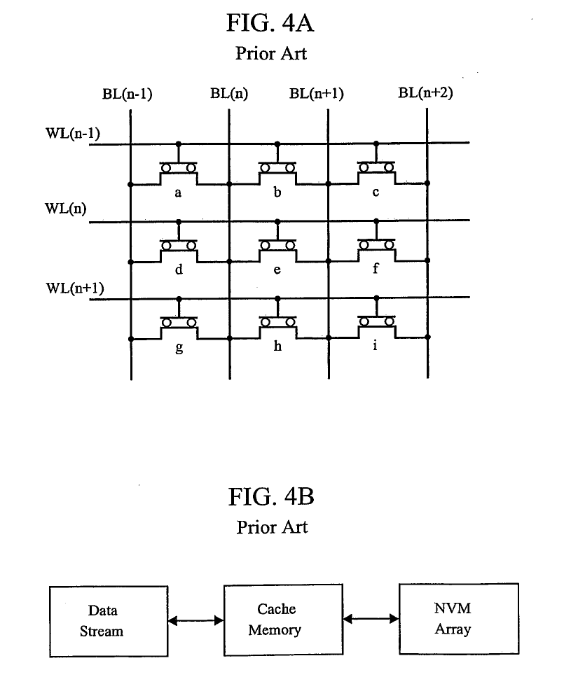

In an embodiment of the disclosure, during programming, “sigma bits” for cells (or half-cells) at each program level may be calculated, as follows.
Each cell has an “index” attached (assigned) to it. An index may be an attribute, such as a physical attribute of the cell (or half-cell) itself, and may, for example, be a number representing or mapping the bit location, in the memory array. The indexes may be based on the SRAM (temporary “cache” storage, described hereinabove with respect to FIG. 4B) addresses of the bits, or a derivative thereof, based on a mathematical operation such as summing, multiplication, or other mathematical operations, described hereinbelow.
The indexes of all of the cells (or half-cells) within the rd-chunk that contains the same program-level are summed, and this becomes the sigma bit (or value) for that program level, for that rd-chunk.

Note that the sigma bits are based on attributes, such as physical attributes of the cells (or half-cells) containing the data, as contrasted with ED bits, which are related to the data itself.

The indexes may be weighted in such as way that each resulting sigma value represents a substantially unique combination of indexes.

For example, assume the following rd-chunk. The indexes are assigned with an increasing weight factor of 2, to provide a unique (or, at least, substantially unique) index combination.

Table of Sigma Bits

| | | | | | | |
|---|---|---|---|---|---|---|
| Indexes- | 2^{2x} | . . . | 2^{x+4} | 2^{x+3} | 2^{x+2} | 2^{x+1} |
| continue | | | | | | |
| indexes | 2^{x} | . . . | 2³ = 8 | 2² = 4 | 2¹ = 2 | 2⁰ = 1 |

And, assume that the indexes 2³=8 and 2¹=2 contain data of the same program level (such as “01”). In this case, the sigma bits for that program level (such as “01”) may be the sum of the (two) indexes 2+8=10.

It should be understood that summing (adding) indexes is but one of various possible mathematical operators that may be performed on the indexes for a plurality of cells at a given program level to enable sorting out overlapping bits in a subsequent read operation (as described hereinbelow).

The sigma bits, which have been calculated for each program level, are associated with and accompany the data being stored and are stored in a manner similar to storing the ED bits which may have been calculated for the data. However, whereas the ED bits are derived from the data itself (such as the number of ones and zeroes), the sigma bits are derived from the addresses (indexes) of bits having different values. As described in greater detail hereinbelow, the ED bits may be used in conjunction with the sigma bits during a read operation to correctly identify which cells (or half cells) were programmed at which program level, despite threshold voltage drift and/or overlap.

In the example set forth above, there is only one unique combination of indexes (2+8) that results in the sigma bit 10 (ten). Therefore, simply by knowing that a sigma bit for a program level (such as “01”) has a value of 10 (ten), it can be deduced (determined) which bits were programmed to that program level (such as “01”).

During read, the sigma bits are read, and this may be done in addition to reading the ED bits. As is known, during read, an entire rd-chunk is read and new ED bits are calculated and compared with the ED bits which have been stored during programming and, if the new ED bits differ from the stored ED bits, an error is identified and corrective measures may be taken, such as shifting read value, as described hereinabove.

In a similar manner, when reading an rd-chunk, new sigma bits (or values) for the stored data are calculated and compared to the stored sigma bits (or values), and a read error is identified (declared) when the new sigma bits differ from the stored sigma bits. (A “read error” implies that it is not immediately apparent which cells were programmed at which program level because of threshold voltage drift, disturb, retention problems and the like.) Corrective measures may then be employed to bring the new and stored sigma values into agreement with one another, thereby enabling determining which cells have been programmed at which program levels.

Generally, the difference (delta) between the newly-calculated and the previously-stored sigma bits may define a unique (or, at least, substantially unique) combination of indexes, enabling searching for, finding and correcting the read errors.

Continuing the previous example, assume that the stored sigma bit value for the given program level (such as “01”) is 10 (ten), as described hereinabove, and that the new sigma bit value for the given program level (such as “01”) is 15 (8+4+2+1), when the data is read. Refer to the Table of Sigma Bits set forth above.

The delta between the newly-calculated Sigma bits (15, fifteen) and the previously-calculated (and stored) Sigma bits (10, ten) is 15−10=5 (five). In this example, this “delta” gives a unique solution where the half-cells indexed 2²=4 and 2⁰=1 (4+1=5) do not belong to the given program level.

It can thus be seen that by having a unique series (or set) of weights for the indexes, unique sigma bits with unique solutions may be produced when there is a distribution overlap. For example, using indexes with the weight series of factor by 2, as described above: 1, 2, 4, 8, 16, . . . generally, any number of read errors can be fixed, using this technique (algorithm).

The “sum of indexes” sigma bits described hereinabove are an example for a mathematical operator on the indexes of an rd-chunk's data. Generally, each sigma index is a fixed amount of bits (such as eight bits), and may be considered to be a virtual address derived from the actual temporary address (in SRAM) of the bits being programmed into the array. Other mathematical operators may alternatively or additionally be used on the indexes including, but not limited to:
An XOR operation on rd-chunk's data.
Rotation of a known vector.
Multiplication of indexes.
Bit-wise operation.
Different weight of indexes.

Generally, these mathematical operations can be performed on the actual temporary address (in SRAM) of the bits being programmed into the array, but generally will be more efficient when performed on the index, which is a virtual address.

The mathematical operation (or combination of operations) is performed on the index of the data, rather than the data itself. This is in contrast with the conventional ED bits which are related to the data itself (such as the number of cells programmed at a given program level).

Each of these mathematical operators presents a different “cell area cost” versus “fixing” ability, and which operator (or group of operators) to be used can be chosen accordingly.

An Analogy

Imagine, if you will, a group of 26 young children, similarly dressed, playing in a school yard, during “recess”. The teacher knows how many boys and girls there are supposed to be in the group, for example, 14 boys and 12 girls. When playtime is over, the teacher gathers the children and first checks (makes a quick count) that there are 26 (this is analogous to the size of the rd-chunk). As a further check, the teacher the separates boys from the girls, and notices that there are 15 boys, and deduces that there are 11 (26−15) girls (this is analogous to the ED bits). One of the girls, sweaty and dirty from playing, has certainly been mistaken for a boy (this is analogous to threshold voltage shift). The discrepancy (started with 14 boys and 12 girls, now have what appears to be 15 boys and 11 girls) is noted. A closer examination must be made.

Now imagine that each of the 26 children has a name starting with a unique one of the 26 letters of the alphabet (from “A” for Albert to “Z” for Zelda). And, that this unique “index” was stored (the “sum” of the first letters of the boys' names forms a “word”, and the “sum” of the first letters of the girls' names forms a different “word”). By “summing” the first letters of the 15 “boys” and comparing against the summed first letters of the 14 boys who were sent out to play, it can readily be determined which of the 15 boys does not belong to the group (“distribution”) of boys. (Hence, the one that does not belong must be a girl.) This illustrates somewhat how the sigma bits work, by operating on a unique attribute of the data, such as its address in SRAM. Each address in SRAM is unique, as are (in this analogy) the first letters of the names of the children. Hence, the sum of addresses, or (more conveniently) indexes associated with the addresses, may provide a unique solution to finding bits which cannot be found by conventional ED techniques (such as the “head count” of boys and girls, in the example).

### Another Embodiment

There may be some practical limitations to the “basic” embodiment described hereinabove, as follows:
For factor-of-2 weighted indexes, the calculated Sigma bits (for a practical rd-chunk size) may be too many. (Increasing an index by power of two can get very large, very quickly.)
Finding, from the whole rd-chunk, the unique combination of indexes that matches the delta between the programmed sigma bits and the newly-calculated sigma bits may be complicated and time consuming.

In this embodiment, a solution for these two limitations may include:
Rather than using factor-of-2 weighted indexes, use an index series which grows slower in order to get fewer sigma bits. For example use the incremental index series: 1, 2, 3, . . .
Rather than searching the whole rd-chunk, define a small list of “suspected” half-cells, that contains only the cells (or half-cells) which are read with error, such as by using the ED bits. In this manner, the unique combination that meets the “sigma delta” may be more quickly identified.

Regarding using other than a factor-or-two weighting for the indexes, an alternative implementation would be to use a simple (linear) weight system for the indexes, such as incremental indexes weights: 1, 2, 3, 4, 5, . . .

Regarding not searching the entire rd-chunk, the cells of the distributions that are non-overlapping may be considered (assumed) to be correctly read, and may be eliminated as a potential source of a problem. The inquiry focuses on the overlap area, or a range of threshold voltages which includes and is slightly larger than the overlap area. For example, once it is determined that there is a problem, the inquiry can be directed to all cells in the top half of the lower distribution and the bottom half of the higher distribution, assuming that the overlap will be included in such a range.

Generally, it is not necessarily “fatal” if all errors are not detected by the techniques disclosed herein, as there are some external ECC techniques that can deal with the “leftovers”, if any. In the least, the techniques disclosed herein can significantly reduce the number of errors to a manageable level.

For example, calculate the sigma bits for bits at the various program levels, and store the sigma bits with the data (this is the same as the “basic” algorithm). In this embodiment, when reading the cells (during “read flow”), find the “suspected” half-cells (or cells), which are defined as follows.
The suspected half-cells may be defined as all half-cells in the distribution overlapping area.
The distribution overlapping area may be detected by the techniques disclosed in the “moving read reference” patents.

All half-cells in the distribution overlapping area are all half-cells that change their value during Moving Read Reference. (Generally, a read is performed, ED bits indicate an erroneous result, the read reference is moved, and the cells which change value are identified as “suspect”.)

FIG. 7B, described hereinabove, illustrates a distribution overlap situation wherein some cells of the Level 1 distribution are at the same threshold voltage as some of the cells of the Level 2 distribution.

A point which can be made, prior to discussing an example of this embodiment, is that the ED and sigma bits may be programmed differently than the data. For example, the data may be programmed with four program levels, which is sensitive to errors, and, the ED and sigma bits can be programmed with only two program levels, widely spaced apart from one another, and may thus be inherently more reliable than the data. Although the error correction algorithms discussed herein may be performed on the ED and sigma bits, by programming them more reliably, they may be assumed to be more trustworthy, thereby negating the need to perform error checking on the ED and sigma bits.

### EXAMPLE

FIG. 8 illustrates an implementation of the algorithm of this embodiment, as follows:

1. Read all of the programmed ED bits and sigma bits. The ED bits are indicative of how many cells have been programmed at each program level. The sigma bits are indicative of attributes of the cells where the data is programmed, such as physical location (as discussed above).

2. First Read (rd1) is done when “Read-Reference” is closer to the “Right” distribution (rather than exactly in-between the two distributions) to ensure that no bits from the “Left” distribution are read with errors. Note, “rd1” is between Level 1 and the pre-shifted (dotted lines) Level 2, and is shown closer to Level 2 (the higher level) than exactly between the two levels.
(a) This guarantees the placement of the “Right” border of the overlapping area (note: throughout explanation left and right can be switched if this is done consistently).
(b) This first read initializes a “suspects table”.

3. If the read fails (which is defined as, in step 2, the calculated ED bits do not agree with the stored ED bits), then move “Read-Reference” and read again (rd2).
Repeat reading until the read is OK (calculated ED bits agrees with programmed ED bits), or until maximum of number of read fixes is reached. (In most cases, a few moves of the read reference should be sufficient.)
Update the suspects table after each read: any half-cell that changes its value from the first read is a “suspect”.

4. If the read fails again, then, if the number of suspects is below an allowed maximum, then move the read-reference (the movement may be with respect to the number of detected suspects) and read again. (It should be noted that the read may succeed (calculated ED=stored ED), but there is nevertheless an overlap. This may occur, for example, if a number of cells moved from “Level 1” to “Level 2”, and an equal number of cells moved from “Level 2” to “Level 1”, in a case of “equal switching”. Generally, if the read fails, there is either an overlap or there may be something wrong with the moving reference.)

At the end of the read, with moving reference of an rd-chunk (steps 1-4), the following data may have been generated, or be available:
Table of suspected half-cells and their indexes, which can be discovered by performing a moving read for each cell that switched.
sigma bits—the target sum of indexes (and/or other mathematical operator).
a number of read errors (referred to as #E), which may be defined as the errors that are leftover from (could not be solved by) moving read. For example, the ED bit for a given level is 300, meaning that 300 cells were programmed at that level, and the moving read reference technique discovered only 290 of those cells. Ten cells are leftover, and need to be found using sigma bits.

5. Find the best combination of #E indexes from the table of suspected half-cells that completes the sum of indexes (or other mathematical operator) of a program-level to its sigma bits.

Using the techniques disclosed herein, all program levels calculations may be done in parallel, and the calculation(s) for a given rd-chunk may be done in parallel with reading and making any necessary calculations for a next rd-chunk.

It may be noted that the overlap shown in FIG. 8 is illustrated as being larger than the overlap shown in FIG. 7B. This is simply to leave enough space for the “rd” arrows in the drawing. The “rd” arrows in the figure symbolize the moving read reference concept according to ED bits. For example, after rd1, ED bits detect that more bits are needed and jumps to rd2. After rd2 is done, ED bits detect there are too many bits and jumping backward is needed—jump to rd3, and so on.

FIG. 8 graphically illustrates an example. In this example, suspected bits may be detected by monitoring the hardware in which data is saved (for example an SRAM) changes which occur every moving read reference.

The first read, “rd1”, reads hardware in which data is saved (for example an SRAM) content. Note that “rd1” is between the pre-shifted Level 2 and Level 1 (which is where the read value RV would be if there were no shift, no ED error, and no overlap). Because there is a read error, the read value is shifted (to the left), and a subsequent read is performed. As mentioned above, rd1 is typically closer to the “right” distribution (Level 2, before shift).

On a second read “rd2”, the bits which changed (apparently program level) can be detected, and the area between rd1 and rd2 are marked as “suspects”.

On a third read “rd3”, the bits between rd1 and rd3 can be marked as suspects, or those between rd2 and rd3, or both, and the same can be done for a fourth read “rd4”.

A “final” read, rd4, may be declared when the result of moving the rd-reference is stable (does not change) with respect to number of detected suspects. The number of reads may be limited to any arbitrary number.

By performing these steps, suspect bits are identified as those bits within a suspected area, which may include the overlap area.

### An Example

An example will be discussed, using the following assumptions:
rd-chunk size is 128 Bytes=1 Kb (1000 bits)
the cells are multi-level cells (MLC), with 4 bits per cell.
Maximum 16 suspected half-cells
Maximum 8 read errors
Minimum Read first bit latency penalty
Minimum Array area penalty

Notes:
the cells may be multi-level cells (MLC), with 4 bits per cell (=2 bits per half-cell)
Maximum 16 suspected half-cells=32 bits suspected to error, 16 analog signals are on suspected area.
Maximum 8 read errors=8 analog signals are errors, E=8
Minimum Read first bit latency penalty—the latency penalty of using the algorithm is reasonable.
Minimum Array area penalty—the area penalty of using the algorithm is reasonable.

### Example, “option 1”

Max total number of combinations is: #Suspect!/((#E−1)!(#Suspect-#E+1)!)=11,440

Note: “!” is the symbol for “factorial”. In mathematics, the factorial of a non-negative integer n is the product of all positive integers less than or equal to n. For example, 5!=1×2×3×4×5=120

| #Suspects | #E | #iterations |
|---|---|---|
| 2 | 1 | 1 |
| 4 | 2 | 4 |
| 6 | 3 | 15 |
| 8 | 4 | 56 |
| 10 | 5 | 210 |
| 12 | 6 | 792 |
| 14 | 7 | 3,003 |
| 16 | 8 | 11,440 |

In general, the number of suspects is assumed to be double (2×) the number of errors, generally because the suspected area may contain overlaps from both the lower and the higher levels. The reality may be more optimal.

The calculation budget time is assumed to be ˜10 μs (ten microseconds, or one thousandth of a second). (Note that the time required for the calculation represents what is called a “latency” penalty, which means that you have to wait for the result of a read request.)

In general, each iteration takes 1 clock cycle, such as 0.05 μs.

In this example, referring to #E=8, going over all of the combinations will take (in a worst case scenario): 11,440*0.05 μs=572 μs.

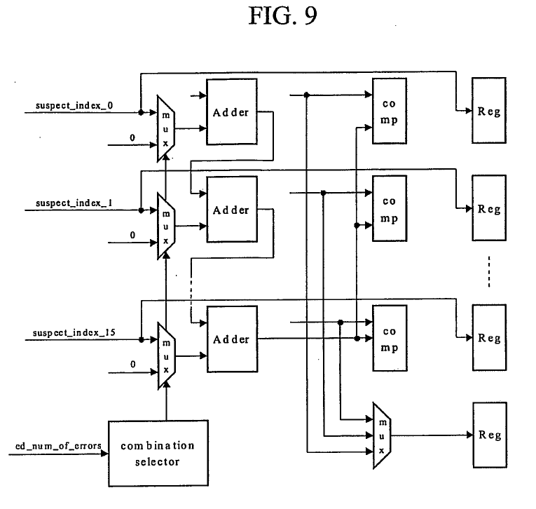

These calculations may be performed by one or more “calculation units”. A hardware implementation of a calculation unit is shown in FIG. 9, described hereinbelow.

If there are 572/10=˜64 calculation units working in parallel, then the worst case calculation time will be 572/64 =˜9 μs, which is within the calculation budget time of ˜10 μs.

Thus, finding the combination that fixes read errors may be done by 64 calculation units working in parallel.

A Hardware (or Software) Implementation

FIG. 9 shows an example of a hardware implementation of a computation unit for performing the aforementioned calculations, implemented in logic units, as follows. The computation unit comprises multiplexers (mux), adders, comparators (comp), and registers (reg), connected as shown. It should be understood that the computation unit, as described herein, may also be implemented in software, performing the functions described herein.

An assumption may be made that each combination of mux/adder/comp will occupy half of the area required by a flip-flop. (The area of a flip-flop is considered to be a standard “yardstick” by which logic area may be measured.)

A logic area “penalty” for the computation unit may therefore be calculated as: 3×{64×[16 FFs+8 FFs+Mux16→8+7×ADDR9bits+16COMP8bits+9 FFs]+16×9b}=9,600FFs

The area for 9,600 FFs is a relatively large area penalty.

### Examples “Option 2”

Max total number of combinations is: #Suspect!/((#E−1)!(#Suspect-#E+1)!)=1,365

| #Suspects | #E | #iterations |
|---|---|---|
| 3 | 1 | 1 |
| 6 | 2 | 6 |
| 9 | 3 | 36 |
| 12 | 4 | 220 |
| 15 | 5 | 1,365 |
| 18 | 6 | 8,568 |
| 21 | 7 | 54,264 |
| 24 | 8 | 346,104 |

In general, the number of suspects is assumed to be triple (3×) the number of errors. The number of suspects is tripled, just for this example. It can be of any rate. Usually it is expected to be about double (2×) of the amount of errors or less.

Again, the calculation budget time is assumed to be ˜10 μs (ten microseconds).

In general, each iteration takes 1 clock cycle, such as 0.05 μs (fifty thousandths of a microsecond).

In this example, referring to #E=5, going over all of the combinations will take (in a worst case scenario): 1,365*0.05 μs=68.25 μs.

These calculations may be performed by one or more “calculation units”. A hardware implementation of a calculation unit is shown in FIG. 9, described hereinabove.

If there are 68.25/10=˜8 calculation units working in parallel, then the worst case calculation time will be 68.25/8=˜9 μs, which is within the calculation budget time of

Finding the combination that fixes read errors may be done by 8 calculation units working in parallel.

The area penalty in this case is a more reasonable 1,200 FFs. (In the previous example, the area penalty was eight times larger, or 9,600 FFs).

In summary (regarding the option 2 results),
the technique described herein can fix up to 3×5=15 read errors per rd-chunk (1,024b). (There may be 3 windows in a 4 b/c product)
add 33 rd-chunks×3 levels×17b=1683b=210B (kept as 2 b/c to be more reliable), resulting in an increase of 10% in Array Area.
˜8% logic area penalty
first bit latency penalty is ˜10 μs

Solving Escape Errors (1)

In the examples set forth above, it was shown how the “overlap problem” can be solved, when the overlap contains all of the errors (if the errors are in the “suspected area”). Situations may exist, however, where errors are outside of the suspected (or overlap) area. Such errors are termed “escape” errors (or “error escape”), and can be solved as follows.

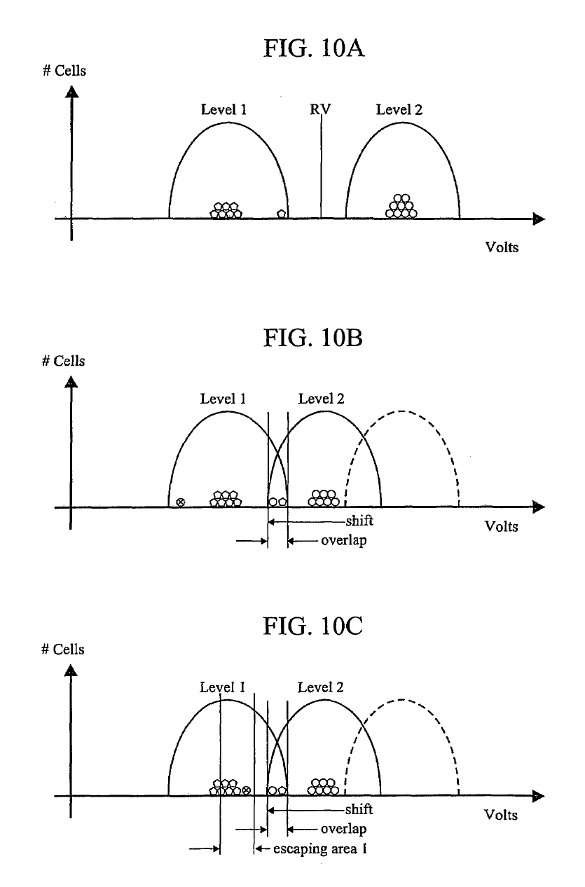

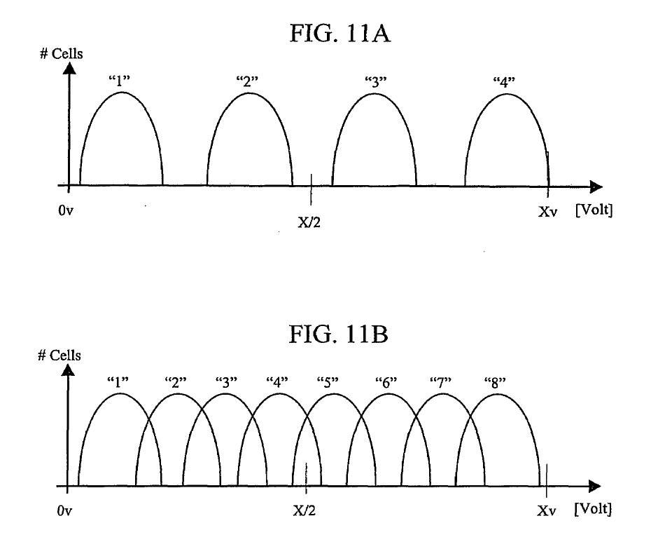

In FIG. 10A (compare FIG. 7A), distributions of bits at two levels, Level 1 and Level 2, are shown. There are 8 bits, shown as polygons (pentagons), in Level 1. There are 9 bits, shown as circles, in Level 2.

In FIG. 10B (compare FIG. 7B), the cells programmed at Level 2 have shifted to the left, and there is an overlap area containing one bit from the Level 1 distribution (that one did not move), and one bit from the Level 2 distribution.

Note that one of the bits from Level 1 was already near the right edge of the Level 1 distribution, before Level 2 shifted, and ends up being in the overlap area, even though it does not move (in this example).

Note that one of the bits from Level 2 has shifted to the near left edge of the Level 2 distribution, and ends up being in the overlap area. Most of (seven of the nine) the bits in Level 2 have shifted substantially uniformly, and are still well within the Level 2 distribution, and could be read using ordinary ED techniques.

Note that one of the bits from Level 2 (the circle with the “X”) has shifted to the left, beyond the overlap area. This error, outside of (beyond) the suspect area is termed an “escaping error”. The escaping error is illustrated as being within the Level 1 distribution, but it could be even further to the left, outside of the Level 1 distribution.

In general, the sigma bit techniques described hereinabove are inadequate for finding this bit. In “error escape” case the suspected area analysis, described hereinabove, may not find any solution, in which case, the following steps may be performed. Two cases are described—“Case 1” for a bit which has escaped on the left side (to a lower Vt, beyond the overlap area), and “Case 2” for a bit which has escaped on the right side (to a higher Vt, beyond an overlap area).

Case 1: Escape on the Left Side
Assume that only 1 bit escapes, in which case no disassembly is needed to refine the search. Generally, the goal is to find a solution to the sigma indexes, each time assuming that only one cell (bit) has escaped, and eventually a match is found. If there is more than one bit, disassembly may be needed to divide the window into separate groups of signals that can be analysed separately. In this case, the escaping bit is not in the suspect group.
Select (N−1) (was #E) suspects out of suspected area and find the “plus complement” to Sigma bits. As used herein, the “plus complement” means the index that completes the sigma bits. Since the sum of indexes was not equal to sigma, no solution was found. Therefore, the inquiry focuses on a smaller group of suspects, and the index is calculated that is needed to add to the group to bring the stored sigma value (which should be a different mathematical operator than was used for finding bits in overlap) into agreement with the stored sigma value. The overall goal is simply to find the missing bit(s).
Check if the complement fits the mathematical operator which was used, such as Bit wise XOR. It should be noted that here, the mathematical operation should be different than the previous one (the one used to find overlapping bits, such as sum of indexes). By programming two different mathematical operators, such as sum, and XOR, there will be more unique combinations that can be used to find missing bits. Generally, by using two or more mathematical operators, redundancy is increased, and the ability to correct (find and identify) errors increases.
If it fits, correct the error. If not assume 2 bits escaped. For 2 or more bits, disassembly is needed.
Select (N−2) suspects out of suspected area and find the plus complement to Sigma bits.
Disassemble complement to escape errors index among new left additional escaping area. Disassembly involved dividing the window into different search areas. See FIG. 10C.
If no combination is found, the assumed escaped errors number may be increased. Increase additional escaping area as well.

Case 2: Escape on the Right Side

(Generally, this is simply the “reverse” of Case 1)
Assume 1 bit escape.
Select (N+1) suspects out of suspected area and find the minus complement to Sigma bits.
Check if combination without complement fits used mathematical operator such as Bit wise XOR.
If it fits, correct the error. If not assume 2 bits escaped.
Select (N+2) suspects out of suspected area and find the minus complement to Sigma bits.
Disassembly complement to escape errors index among new right additional escaping area.

It should be noted that the two cases (Case 1, Case 2) described hereinabove may also be implemented in parallel to previous steps, such as finding bits with overlapping threshold voltages, in which case the algorithm calculation time can be accelerated.

Increasing Solving Probability

In order to increase solving probability, different operators can be used, and more operators can be used at once, such as (but not limited to):
Sigma
Bit Wise XOR
Additional Bit-wise Logical Operators, such as (but not limited to):
   2-Inhibition (by order of SRAM indexes)
   4-Inhibition
   1-Implication
   13-Implication

The table below is a logic truth table for additional logical operators

| X | Y | 2-Inhibition | 4-Inhibition | 11-Inhibition | 13-Inhibition |
|---|---|---|---|---|---|
| 0 | 0 | 0 | 0 | 1 | 1 |
| 0 | 1 | 0 | 1 | 0 | 1 |
| 1 | 0 | 1 | 0 | 1 | 0 |
| 1 | 1 | 0 | 0 | 1 | 1 |

Reduce Redundancy Cost
Redundancy is additional data that needs to be stored due to the ECC.
To reduce new algorithm redundancy, the ED bits do not need to be stored in 2 bpc, they can be stored on 4 bpc. Recall that storing 2 bpc is generally more reliable than 4 bpc, which is why the ED or sigma bits stored at 2 bpc were generally considered to be more reliable than the data which is stored at 4 bpc. Here, it is proposed that the ED bits be stored at the same reliability level (4 bpc) as the data. The sigma bits (whether the set of one mathematical operator, or two or more mathematical operators) may yet be stored at the more reliable resolution of 2 bpc.
   To increase efficiency, the redundancy of the algorithm may be stored on available half-cell of the ED bits.
On products which have OTP option for user chunk size, the spare bits available when using OTP lower user chunk size can be used for storing the sigma bits

Recursion
The Algorithm can be used in recursive way: perform the algorithm upon itself. This can be in conjunction with storing the sigma bits in a less reliable (and less consumptive of memory) manner, such as 4 bpc rather than 2 bpc. By performing the ECC technique upon the sigma bits, a comparable level of reliability can be achieved.
An example of recursive use is to activate the algorithm upon its own redundancy information, when it is performed on one or more rd-chunks. By doing this, the following gains can be made:
   Less redundant information to store
   Recursive can be performed on other parameters as well
The recursion can be preformed several times or more, upon itself, upon redundancy data or upon its parameters. Each time recursion is performed, the gain may be less redundancy to store or other benefits.

Programming with Overlap

Usually, bits are programmed at program levels having distinct threshold voltages, and these program levels are nicely separated from one another. In this manner, read voltage levels can be established in the gaps (windows) between adjacent program levels. See, for example, FIGS. 5A and 5B.

The techniques disclosed herein enable sorting out bits that were programmed at different threshold voltages, in distinct program level distributions, which later drifted (shifted) so that some of the bits programmed with a threshold voltage at one program level overlap some of the bits programmed with a threshold voltage at another (adjacent) program level. Generally, the redundancy provided by sigma bits allows the bits to be sorted out.

A benefit of the techniques disclosed herein is that they allow for the program levels to be much closer than before, including overlapping.

FIG. 11A shows a conventional distribution of four program levels (“1”, “2”, “3”, “4”) over a given range of voltages, from approximately 0 volts to approximately X volts. Notice that each program level occupies a range of voltages which is separate and distinct from the range of voltages of the neighboring program level(s). (In binary terms, the four program levels may represent “00”, “01”, “1” and “10”, as described above).

The problems associated with sorting out which bits were programmed at which program level when the threshold voltages have shifted to the extent that the voltage distributions run into each other (overlap), have been discussed above.

FIG. 11B shows that four program levels (“1”, “2”, “3”, “4”) may be programmed over a smaller range of voltages, such as from approximately 0 volts to approximately X/2 (one half of X) volts, and, that an additional four program levels (“5”, “6”, “7”, “8”) may be programmed over a remainder of the overall range of voltages, such as from approximately X/2 volts to approximately X volts. (In binary terms, the eight program levels may represent “000”, “001”, “011”, “010”, “110”, “111”, “101”, and “100”.)

Using the techniques disclosed herein, bits programmed at the different program levels can be “sorted out”, so that it can be determined at what program level they were programmed, despite overlapping threshold voltages. In this manner, by enabling more program levels in a given voltage range, more data can be stored. In this example, twice as much data (eight program levels rather than four program levels) can be stored.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. A method of operating non-volatile memory (NVM) array comprising:
during programming, calculating sigma bits for cells storing data at each program level based on attributes of the cells at the program level; and
storing the sigma bits in the memory array along with data.

2. The method of claim 1, wherein the sigma bit is based on, an index representing a cell's bit location in the memory array.

3. The method of claim 2, wherein the index is based on a temporary cache storage address for the bits being programmed into the memory array.

4. The method of claim 1, wherein calculating sigma bits comprises a mathematical operation on indexes for the cells at each program level.

5. The method of claim 4, wherein the mathematical operation is selected from the group consisting of:
summing the indexes;
an XOR operation on rd-chunk's data;
rotation of a known vector;
multiplication of indexes;
bit-wise operation; and
different weight of indexes.

6. The method of claim 4, wherein the indexes are assigned with an increasing weight factor.

7. The method of claim 6, wherein the increasing weight factor comprises factor-of-2.

8. The method of claim 1, further comprising:
during read, calculating new sigma bits for the stored data and comparing the new sigma bits to the stored sigma bits, and declaring a read error when the new sigma bits differ from the stored sigma bits.

9. The method of claim 1, further comprising:
a difference between the new sigma bits and the stored sigma bits defines a unique combination of indexes, enabling searching for, finding and correcting the read errors.

10. The method of claim 1, further comprising:
during read, using the sigma bits to correctly identify which cells were programmed at which program level, despite threshold voltage drift and/or overlap.

11. The method of claim 1, further comprising:
using ED bits in conjunction with the sigma bits during a read operation to correctly identify which cells (or half-cells) were programmed at which program level.

12. The method of claim 1, wherein:
the sigma bits define a unique combination of indexes, enabling searching for, finding and correcting read errors.

13. The method of claim 1, wherein:
the sigma bits are based on indexes for the cells storing data; and
the indexes are assigned in a manner to provide substantially unique index combinations for bits at the different program levels.

14. The method of claim 13, further comprising:
using an incremental series of indexes.

15. The method of claim 1, further comprising:
during read, calculating new sigma bits for the stored data and comparing the new sigma bits to the stored sigma bits; and
defining a list of suspect cells that may contain read errors, such as by using ED bits, and using the list of suspect cells to identify a unique combination that brings the calculated sigma bits into agreement with the stored sigma bits.

16. The method of claim 15, wherein the suspect cells are located using a moving read reference.

17. The method of claim 17, wherein a list of suspect cells comprises cells in two program level distributions that have overlapping threshold voltages.

18. A method of programming data in non-volatile memory (NVM) comprising:
programming a chunk of data in a plurality of cells of a memory array;
programming ED bits along with the data, wherein the ED bits are indicative of how many cells have been programmed at each program level; and
programming sigma bits along with the data, wherein the sigma bits are indicative of attributes of the cells where the data is programmed.

19. The method of claim 18, further comprising:
reading the chunk of data; and
reading the programmed ED bits and sigma bits.

20. The method of claim 19, wherein:
the data is programmed in at least two distributions, one of which is a right distribution, the other of which is a left distribution; and
a first read is done with a read reference (rd1) closer to the right distribution to ensure that no bits from the left distribution are read with errors.

21. The method of claim 20, further comprising:
initializing a suspects table.

22. The method of claim 21, further comprising:
calculating ED bits for the chunk of data being read and, if the calculated ED bits do not agree with the stored ED bits, then moving the read reference and repeating reading until the calculated ED bits agree with programmed ED bits, or until a maximum number of read fixes is reached; and
updating the suspects table after each read.

23. The method of claim 21, further comprising:
finding a best combination of indexes from the suspects table suspected half-cells that completes the sum of indexes (or other mathematical operator) of a program-level to its sigma bits.

24. A method of operating non-volatile memory (NVM) array comprising:
programming different program levels with overlapping threshold voltage distributions.

25. The method of claim 24, further comprising:
when reading, sorting out bits programmed at the different program levels and having overlapping threshold voltages.
